(19) United States
(12) Patent Application Publication
(10) Pub. No.: US 2012/0064460 A1
(43) Pub. Date: Mar. 15, 2012

(54) MOVABLE BODY APPARATUS, OBJECT PROCESSING DEVICE, EXPOSURE APPARATUS, FLAT-PANEL DISPLAY MANUFACTURING METHOD, AND DEVICE MANUFACTURING METHOD

(75) Inventor: Yasuo AOKI, Zushi-shi (JP)

(73) Assignee: NIKON CORPORATION, Tokyo (JP)

(21) Appl. No.: 13/223,970

(22) Filed: Sep. 1, 2011

Related U.S. Application Data
(60) Provisional application No. 61/380,433, filed on Sep. 7, 2010.

(51) Int. Cl. G03F 7/20; B65G 1/133; G03B 27/42

(52) U.S. Cl. 430/320; 355/53; 430/325; 414/749.1

(57) ABSTRACT

By a substrate support member moving in predetermined strokes in a scanning direction on a Y step surface plate, a substrate held by the substrate support member moves in the scanning direction in predetermined strokes in a state supported from below by an air floating device. Further, because a Y step guide having an air floating device moves in a cross-scan direction along with the substrate holding member, the substrate can be moved optionally in the scanning direction, and/or in the cross-scan direction. In doing so, because the Y step surface plate moves in the cross-scan direction with the substrate support member and the Y step guide, the substrate support member is constantly supported by the Y step surface plate.

### CROSS-REFERENCE TO RELATED APPLICATIONS

This non-provisional application claims the benefit of Provisional Application No. 61/380,433 filed Sep. 7, 2010, the disclosure of which is hereby incorporated herein by reference in its entirety.

### BACKGROUND OF THE INVENTION

1. Field of the Invention

The present invention relates to movable body apparatuses, object processing devices, exposure apparatuses, flat-panel display manufacturing methods, and device manufacturing methods, and more particularly to a movable body apparatus which moves an object along a predetermined two-dimensional plane, an object processing device which performs a predetermined processing on an object held by the movable body apparatus, an exposure apparatus which forms a predetermined pattern on an object held by the movable body apparatus, a flat-panel display manufacturing method which uses the exposure apparatus, and a device manufacturing method which uses the exposure apparatus.

2. Description of the Background Art

Conventionally, in a lithography process for manufacturing electron devices (microdevices) such as liquid crystal display devices and semiconductor devices (such as integrated circuits), exposure apparatuses such as a projection exposure apparatus by a step-and-repeat method (a so-called stepper), or a projection exposure apparatus by a step-and-scan method (a so-called scanning stepper (which is also called a scanner) is mainly used.

In this type of exposure apparatus, the object (a glass plate, or a wafer (hereinafter, generally referred to as a “substrate”)) subject to exposure is mounted on a substrate stage device. And a circuit pattern formed on a mask (or a reticle) is transferred onto a substrate by irradiation of an exposure light via an optical system such as a projection lens. (e.g., refer to U.S. Patent Application Publication No. 2010/0018950).

Now, in recent years, substrates subject to exposure of exposure apparatuses, especially rectangular shaped glass plates used for liquid crystal displays, tend to increase in size such as, for example, one side being 3 meters or more, which causes the size of the substrate stage device to increase, as well as the weight. Therefore, development of a compact lightweight stage device that can control the position of an exposure object (substrate) at a high speed with high precision was desired.

### SUMMARY OF THE INVENTION

According to a first aspect of the present invention, there is provided a movable body apparatus, comprising: a first movable body which holds an edge of an object placed along a predetermined two-dimensional plane that is parallel to a horizontal plane, and is movable with predetermined strokes at least in a first direction within the two-dimensional plane; a second movable body which includes an object support member that supports the object from below within a movable range in the first direction of the first movable body, and is movable in a second direction orthogonal to the first direction within the two-dimensional plane along with the first movable body; and a third movable body which is vibrationally separated from the object support member at least in the first direction, supports the first movable body from below within a movable range of the first movable body in the first direction, and is movable along with the second movable body in the second direction.

According to the apparatus, by the first movable body moving in predetermined strokes in the first direction on the third movable body, the object held by the first movable body moves in the first direction in predetermined strokes in a state where the object is supported from below by an object support member. Further, because the second movable body having the object support member moves in the second direction along with the first movable body, the object can be driven optionally in the first direction and/or the second direction. In doing so, because the third movable body moves in the second direction along with the first and second movable bodies, the first movable body is constantly supported by the third movable body. Further, because the object is constantly supported from below by the object support member within its movable range, bending due to its self-weight is suppressed. Accordingly, reducing the weight and size of the device becomes possible compared with the case when the object is mounted on a holding member that has about the same area as the object, and the holding member is driven. Further, because the second movable body and the third movable body are vibrationally separated at least in the first direction, vibration, reaction force and the like which are generated in the first direction, for example, when the first movable body moves in the first direction can be kept from travelling between the second and third movable bodies.

According to a second aspect of the present invention, there is provided an object processing device, comprising: the movable body apparatus of the present invention; and an execution device which executes a predetermined operation from a side opposite to the holding device to a portion held by the holding device of the object, to perform a predetermined processing on the object.

According to a third aspect of the present invention, there is provided a first exposure apparatus, the apparatus comprising: the apparatus comprising: the movable body apparatus of the present invention; and a pattern formation apparatus which exposes the object with an energy beam and forms a predetermined pattern on the object.

According to a fourth aspect of the present invention, there is provided a flat-panel display manufacturing method, comprising: exposing the substrate using the exposure apparatus of the present invention; and developing the substrate that has been exposed.

According to a fifth aspect of the present invention, there is provided a device manufacturing method, comprising: exposing an object using the exposure apparatus of the present invention; and developing the object that has been exposed.

According to a sixth aspect of the present invention, there is provided a second apparatus that exposes an object with an energy beam and forms a pattern on the object, the apparatus comprising: a first movable body which holds an edge of an object placed along a predetermined two-dimensional plane that is parallel to a horizontal plane, and is movable with predetermined strokes at least in a first direction within the two-dimensional plane; a second movable body which includes an object support member that supports the object from below within a movable range in the first direction of the first movable body, and is movable in a second direction orthogonal to the first direction within the two-dimensional plane along with the first movable body; and a third movable body which is vibrationally separated from the object support member at least in the first direction, supports the first movable body from below within a movable range of the first movable body in the first direction, and is movable along with the second movable body in the second direction; and an exposure system which exposes the object with the energy beam.

According to a seventh aspect of the present invention, there is provided a flat-panel display manufacturing method, comprising: exposing the substrate using the second exposure apparatus described above; and developing the substrate that has been exposed.

According to an eighth aspect of the present invention, there is provided a device manufacturing method, comprising: exposing the object using the second exposure apparatus described above; and developing the object that has been exposed.

### BRIEF DESCRIPTION OF THE DRAWINGS

In the accompanying drawings;

FIG. 1 is a view that schematically shows a configuration of a liquid crystal exposure apparatus of a first embodiment;

FIG. 2 is a planar view of a substrate stage device which the liquid crystal exposure apparatus of FIG. 1 has;

FIG. 3 is a planar view of a Y step surface plate which the substrate stage device in FIG. 2 has;

FIG. 4 is a sectional view of line B-B in FIG. 3;

FIG. 5 is a planar view of a base surface plate and a Y step surface plate which the substrate stage device in FIG. 2 has;

FIG. 6 is a sectional view of line C-C in FIG. 5;

FIG. 7A is a planar view of a substrate support member that the substrate stage device in FIG. 2 has, and FIG. 7B is a sectional view of line D-D in FIG. 7A;

FIG. 8 is a sectional view of the fixed point stage which a substrate stage device in FIG. 2 has;

FIGS. 9A and 9B are views (Nos. 1 and 2) used to explain an operation of the substrate stage device at the time of exposure processing;

FIGS. 10A and 10B are views (Nos. 3 and 4) used to explain an operation of the substrate stage device at the time of exposure processing;

FIG. 11 is a planar view of a substrate stage device related to a second embodiment;

FIG. 12 is a sectional view of line E-E in FIG. 11;

FIG. 13 is a planar view of a substrate stage device related to a third embodiment;

FIG. 14 is a sectional view of line F-F in FIG. 13;

FIG. 15 is a planar view of a substrate stage device related to a fourth embodiment;

FIG. 16 is a sectional view of line G-G in FIG. 14;

FIG. 17 is a planar view of a substrate stage device related to a fifth embodiment;

FIG. 18 is a sectional view of line H-H in FIG. 17; and

FIGS. 19A and 19B are figures showing a modified example (No. 1 and 2) of the substrate support member.

### DESCRIPTION OF THE EMBODIMENTS

### First Embodiment

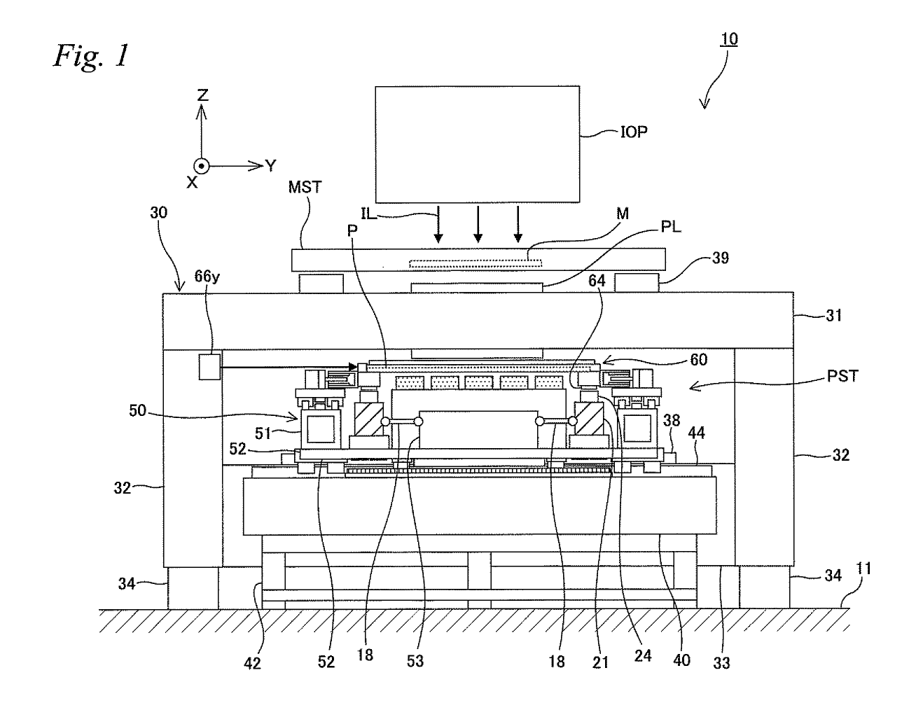

A first embodiment will be described below, with reference to FIGS. 1 to 10B.

FIG. 1 schematically shows a configuration of an exposure apparatus 10 related to the first embodiment. Liquid crystal exposure apparatus 10 is a projection exposure apparatus by a step-and-scan method, or a so-called scanner in which a rectangular glass substrate P (hereinafter, simply referred to as a substrate P) that is used in a liquid crystal display device (flat panel display) serves as an exposure subject.

As shown in FIG. 1, liquid crystal exposure apparatus 10 is equipped with an illumination system TOP, a mask stage MST holding a mask N, a projection optical system PL, a device main section 30 supporting mask stage MST, projection optical system PL and the like, a substrate stage device PST holding substrate P, and a control system and the like thereof. In the description below, the explanation is given assuming that a direction in which mask M and substrate Pare scanned relative to projection optical system PL, respectively, during exposure is an X-axis direction, a direction orthogonal to the X-axis direction within a horizontal plane is a Y-axis direction, and a direction orthogonal to the X-axis and Y-axis directions is a Z-axis direction, and rotational (tilt) directions around the X-axis, Y-axis and Z-axis are θx, θy and θz directions, respectively. Further, positions in the X-axis, the Y-axis, and the Z-axis directions will each be described as X position, Y position, and Z position.

Illumination system IOP is configured similar to the illumination system that is disclosed in, for example, U.S. Pat. No. 6,552,775 and the like. More specifically, illumination system IOP irradiates mask M with a light emitted from a light source that is not illustrated (e.g. a mercury lamp), as an illumination light for exposure (illumination light) IL, via a reflection mirror, a dichroic mirror, a shutter, a wavelength selecting filter, various types of lenses and the like, which are not illustrated. As illumination light IL, for example, a light such as an i-line (with a wavelength of 365 nm), a g-line (with a wavelength of 436 nm) or an h-line (with a wavelength of 405 nm) (or a synthetic light of the i-line, the g-line and the h-line described above) is used. Further, the wavelength of illumination light IL can be appropriately switched by the wavelength selecting filter, for example, according to the required resolution.

On mask stage MST, mask M having a pattern surface (the lower surface in FIG. 1) on which a circuit pattern and the like are formed is fixed by, for example, vacuum suction. Mask stage MST is mounted in a non-contact manner on a pair of mask stage guides 39 fixed on a barrel surface plate 31 which is a part of device main section 30, and is driven, for example, by a mask stage drive system (not illustrated) including a linear motor in a scanning direction (the X-axis direction) with predetermined strokes, and is also finely driven appropriately in the Y-axis direction, and the θz direction. Positional information (including rotation information in the θz direction) in the XY plane of mask stage MST is measured by a mask interferometer system that includes a laser interferometer which is not illustrated.

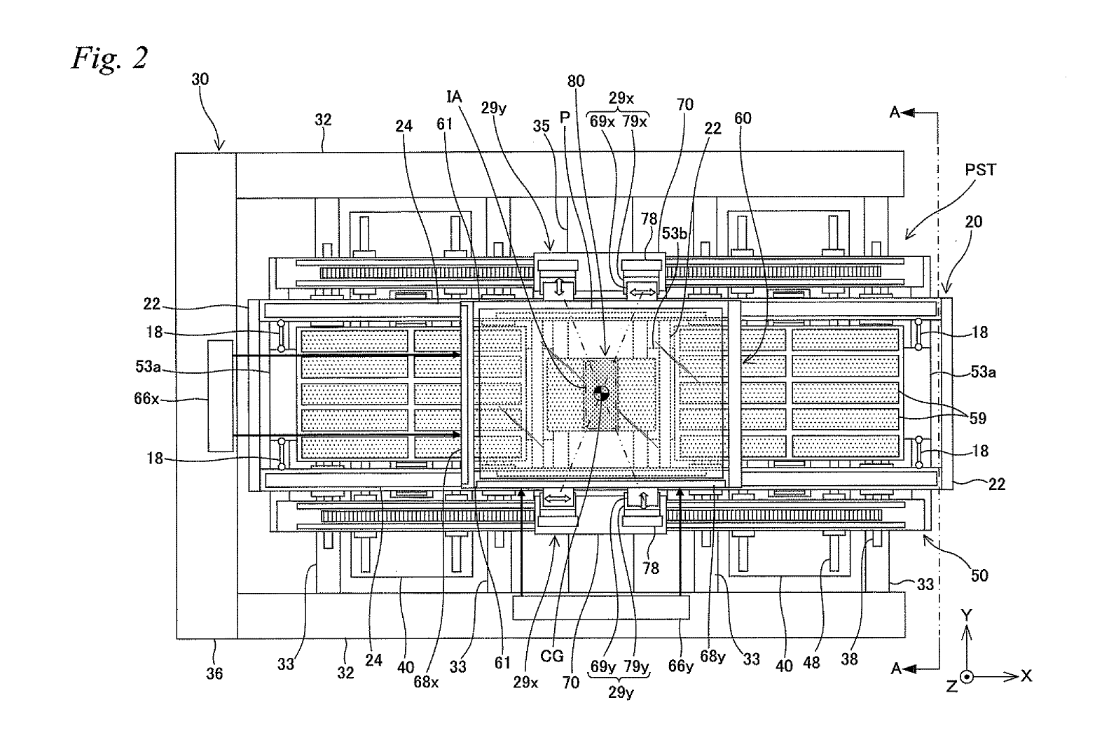

Projection optical system PL is supported below mask stage MST in FIG. 1, by a barrel surface plate 31 which is a part of device main section 30. Projection optical system PL of the embodiment has a configuration similar to the projection optical system disclosed in, for example, U.S. Pat. No. 6,552,775. More specifically, projection optical system PL includes a plurality of projection optical systems (multi-lens projection optical systems) whose projection areas, where a pattern image of mask M is projected, are placed in a zigzag shape, and functions equivalently to a projection optical system that has a single image field with a rectangular shape whose longitudinal direction is in the Y-axis direction. In the embodiment, as each of the plurality of projection optical systems, for example, a projection optical system that is a both-side telecentric equal-magnification system that forms an erected normal image is used. In the description below, the plurality of projection areas placed in a zigzag shape of projection optical system PL are referred to as an exposure area IA (refer to FIG. 2) as a whole.

Therefore, when an illumination area on mask M is illuminated with illumination light IL from illumination system IOP, by illumination light IL that has passed through mask M, a projected image (partial erected image) of a circuit pattern of mask M within the illumination area is formed, via projection optical system PL, on an irradiation area (exposure area IA) of illumination light IL, which is conjugate to the illumination area, on substrate P whose surface is coated with a resist (sensitive agent). Then, by moving mask M relative to the illumination area (illumination light IL) in the scanning direction (X-axis direction) and also moving substrate P relative to exposure area IA (illumination light IL) in the scanning direction (X-axis direction) by a synchronous drive of mask stage MST and substrate stage PST, scanning exposure of one shot area (divided area) on substrate P is performed, and a pattern of mask M (mask pattern) is transferred onto the shot area. More specifically, in the embodiment, a pattern of mask M is generated on substrate P by illumination system IOP and projection optical system PL, and the pattern is formed on substrate P by exposure of a sensitive layer (resist layer) on substrate P with illumination light IL.

Device main section 30 includes barrel platform 31 previously described, a pair of side columns 32 that support each of the vicinity of the ends of barrel platform 31 on the +Y side and the −Y side from below, a plurality of lower columns 33 extending in between a pair of opposing surfaces of the pair of side columns 32 that face each other, and a fixed point stage mounting 35 (not illustrated in FIG. 1, refer to FIG. 2) that supports a fixed point stage 80 which will be described later on from below. Each of the pair of side columns 32 are mounted on a vibration isolator 34 installed on a floor 11 of a clean room. This vibrationally separates mask stage MST described above supported by device main section 30 and projection optical system PL with respect to floor 11. Incidentally, in FIGS. 2, 3, and 9A to 10B, device main section 30 is shown with barrel platform 31 removed, for the sake of clarity.

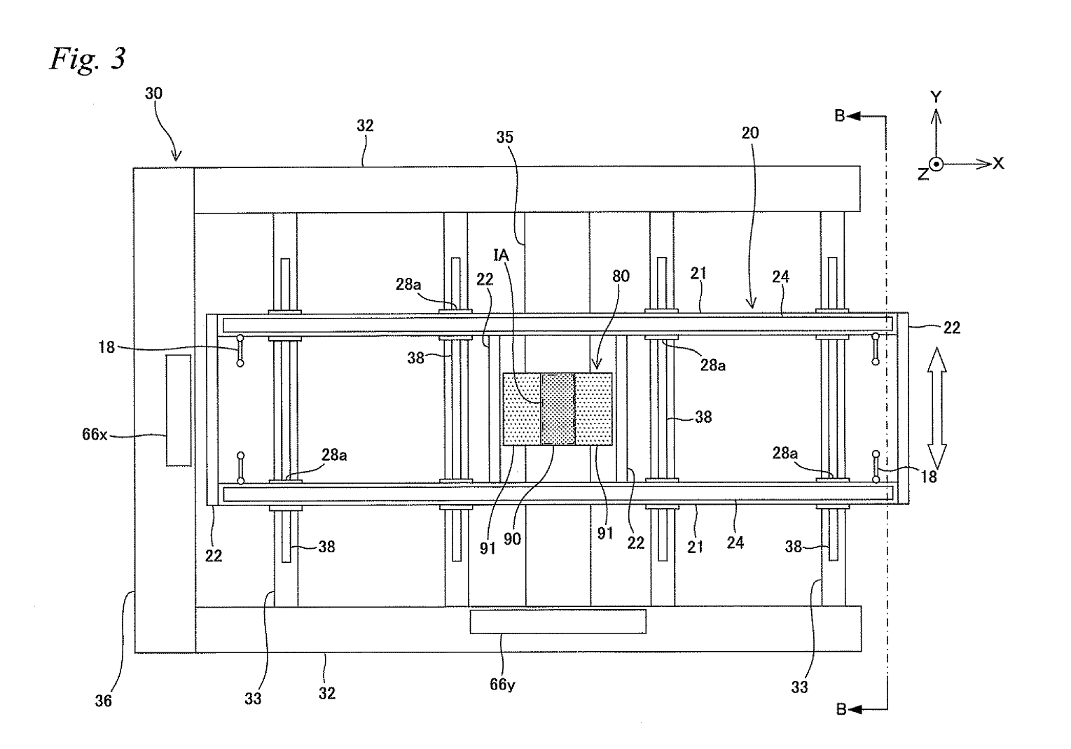

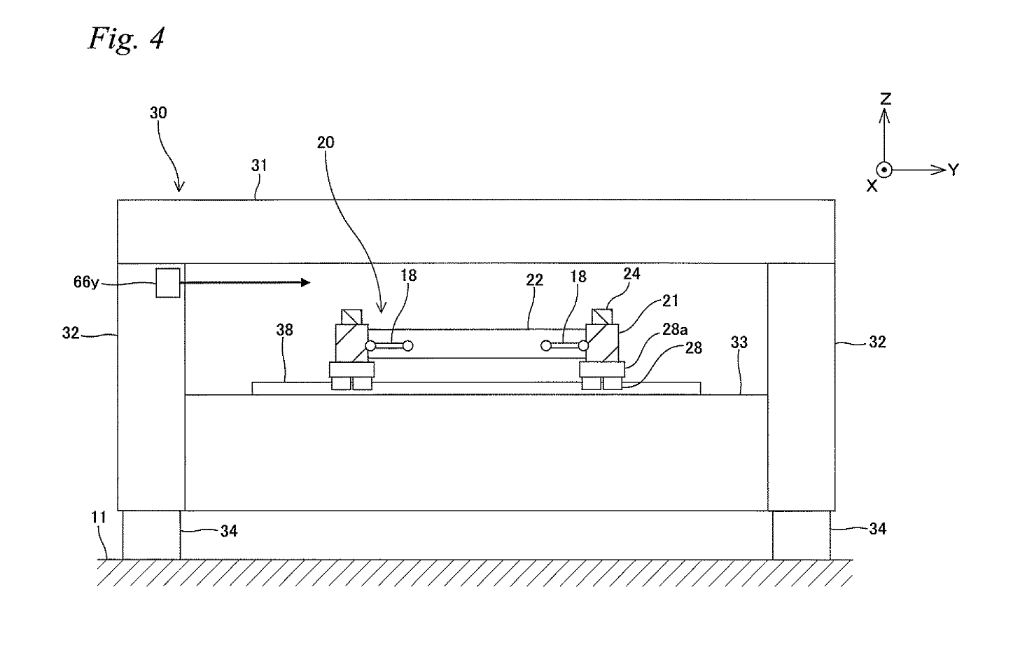

As shown in FIGS. 3 and 4, lower column 33 consists of a plate shaped member which is elongated in the Y-axis direction having a predetermined thickness and is placed parallel to the YZ plane, and for example, 4 columns are provided in the X-axis direction at a predetermined distance. To the upper surface of lower column 33, a Y linear guide 38 extending parallel to the Y-axis is fixed. Fixed point stage mounting 35 consists of a plate shaped member which is elongated in the Y-axis direction and parallel to the YZ plane that is thicker (dimension (length) in the X-axis direction is longer) than lower column 33, and is installed extending in between the opposing surfaces of the pair of side columns 32 that face each other. Accordingly, fixed point stage mounting 35 is vibrationally separated with respect to floor 11 by vibration isolator 34, via the pair of side columns 32. Of the four lower columns 33 described above, for example, two are placed on the +X side of fixed point stage mounting 35, and the other two are placed on the −X side of fixed point stage mounting 35.

Substrate stage device PST, as shown in FIG. 2, is equipped with a Y step surface plate 20, a pair of base surface plates 40, a Y step guide 50, a substrate support member 60, a fixed point stage 80 and the like. Incidentally, while substrate stage device PST in the general view of liquid crystal exposure apparatus 10 shown in FIG. 1 is equivalent to the sectional view of line A-A in FIG. 2, lower column 33 (and Y linear guides 38 fixed to the upper surface of lower column 33) located outermost on the +X side (nearest when viewed from the +X side) is omitted for the sake of clarity of the configuration of substrate stage device PST.

As shown in FIG. 3, Y step surface plate 20 includes a pair of X beams 21, a plurality of, e.g., four, interlinking members 22 and the like. The pair of X beams 21 each consist of a member whose YZ shape is rectangular, extending in the X-axis direction (refer to FIG. 4), and are placed parallel to each other. The distance between the pair of X beams 21 is set substantially to the same dimension as the length (dimension) of substrate P in the Y-axis direction, and the length (dimension) of X beams 21 in the X-axis direction is set to cover a movement range of substrate P in the X-axis direction. For example, four interlinking members 22 mechanically connects the pair of X beams 21 to each other in two places; the vicinity of both ends in the longitudinal direction of the pair of X beams 21, and the mid section in the longitudinal direction. The four interlinking members 22 each consist of a plate shaped member extending in the Y axis direction.

To the lower surface of each of the pair of X beams 21, a plurality of Y sliders 28 are fixed via a spacer 28a as shown in FIG. 4. As shown in FIG. 3, for one X beam 21, for example, four spacers 28a are provided, corresponding to the plurality of Y linear guides 38 described above. Y slider 28 consists of a member whose XZ section is an inverted U-shape, includes a plurality of balls that are not illustrated, and engages slidable with low friction with Y linear guides 38. As shown in FIG. 4, for one spacer 28a, for example, two Y sliders 28 are provided spaced apart in the Y-axis direction. As described, Y step surface plate 20 is mounted, for example, movable in predetermined strokes in the Y-axis direction on four lower columns 33.

To each of the upper surfaces of the pair of X beams 21, an X guide 24 is fixed, as shown in FIG. 3. X guide 24, as shown in FIG. 4, consists of a member whose YZ sectional shape is rectangular, extending in the X-axis direction, and is formed by, for example, a stone material (or ceramics), and its upper surface is finished so as to have a very high flatness degree.

Referring back to FIG. 2, one of the pair of base surface plates 40 is inserted in between the pair of lower columns 33 placed on the +X side of fixed point stage mounting 35, via a predetermined clearance (in a state non-contact to lower column 33), and the other is inserted in between the pair of lower columns 33 placed on the −X side of fixed point stage mounting 35, via a predetermined clearance (in a state non-contact to lower column 33). While device main section 30 previously described and the pair of base surface plate 40 are both installed on floor 11, because device main section 30 is vibrationally separated by vibration isolator 34 with respect to floor 11, device main section 30 and the pair of base surface plates 40 are vibrationally separated from each other. Because the pair of base surface plates 40 each are configured substantially the same except that the placement is different, hereinafter, only base surface plate 40 on the +X side will be described.

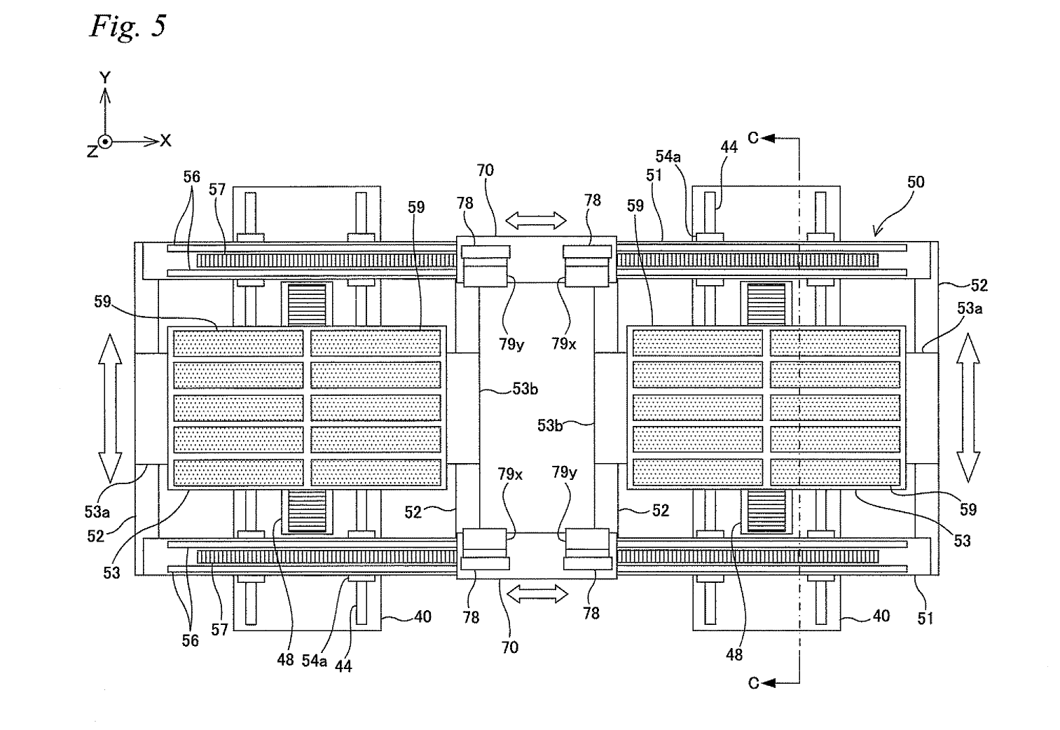

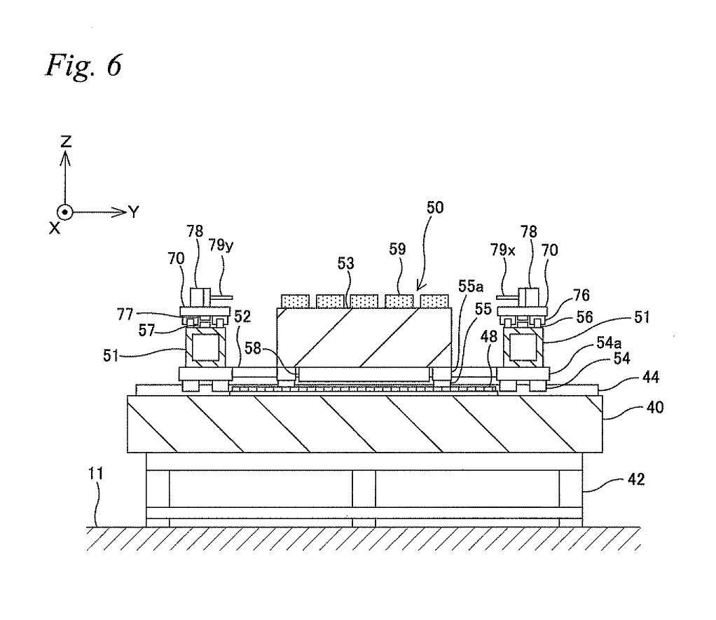

As it can be seen from FIGS. 5 and 6, base surface plate 40 consists of a rectangular parallelepiped member whose longitudinal direction is in the Y-axis direction in a planar view, and is installed on floor 11 via a mounting 42 (not illustrated in FIG. 5, refer to FIG. 6). Near the edge on the +X side and the −X side on the upper surface of base surface plate 40, Y linear guides 44 extending in the Y-axis direction are fixed parallel to each other, as shown in FIG. 5. Further, to the center on the upper surface of base surface plate 40, a Y stator 48 is fixed. Y stator 48, in this case, has a magnet unit including a plurality of magnets arranged at a predetermined distance in the Y-axis direction. Incidentally, as long as the pair of base surface plates 40 and/or mounting 42 are not in contact with device main section 30, they can be connected to each other. Further, mounting 42 can be placed on floor 11 via a vibration isolator which is not illustrated.

As shown in FIG. 6, Y step guide 50 is mounted on the pair of base surface plates 40. As shown in FIG. 5, Y step guide 50 includes a pair of X beams 51, a plurality of, e.g., four, interlinking members 52, a pair of air floating device bases 53, a plurality of air floating devices 59, a pair of X carriage 70 and the like.

Each of the pair of X beams 51 consists of a hollow member (refer to FIG. 6) whose YZ sectional shape is rectangular, extending in the X-axis direction. Four interlinking members 52 mechanically connects the pair of X beams 51 to each other in two places; the vicinity of both ends in the longitudinal direction of the pair of X beams 51, and the mid section in the longitudinal direction. Each of the four interlinking members 52 consists of a plate shaped member extending in the Y-axis direction, and on the upper surface near the edge on the +Y side, the +Y side of X beam 51 is mounted, whereas on the upper surface near the edge on the −Y side, the −Y side of X beam 51 is mounted, as shown in FIG. 1. Further, as shown in FIG. 1, the Z position of the lower surface of each of the plurality of interlinking members 52 is higher (the +Z side) than the Z position of the upper surface of lower column 33, and Y step guide 50 and device main section 30 are non-contact (Y step guide 50 passes above lower column 33).

To the lower surface of each of the pair of X beams 51, a plurality of Y sliders 54 are fixed via a spacer 54a as shown in FIG. 6. As shown in FIG. 5, for one X beam 51, for example, four spacers 54a are provided, corresponding to the plurality of Y linear guides 44 described above. Y slider 54 consists of a member whose XZ section is an inverted U-shape, includes a plurality of balls that are not illustrated, and engages slidable with low friction with Y linear guides 44. As shown in FIG. 6, for one spacer 54a, for example, two Y sliders 54 are provided spaced apart in the Y-axis direction. As described, Y step guide 50 is mounted movable in predetermined strokes in the Y-axis direction on the pair of base surface plates 40.

To the upper surface of each of the pair of X beams 51, as shown in FIG. 5, a pair of X linear guides 56 extending in the X-axis direction are fixed parallel to each other. Further, on the upper surface of each of the pair of X beams 51 in the area between the pair of X linear guides 56, an X stator 57 is fixed. X stator 57 has a magnet unit including a plurality of magnets arranged at a predetermined distance in the X-axis direction.

The pair of air floating device bases 53 each consists of a rectangular parallelepiped shape (a box like) member whose longitudinal direction is in the X direction in a planar view, and in a state shown in FIG. 2 where substrate stage PST is assembled, are placed on the +X side and −Y side of fixed point stage 80. Referring back to FIG. 5, to the side surface on the +X side of air floating device base 53 on the +X side and to the side surface on the −X side of air floating device base 53 on the −X side, respectively, a connecting member 53a consisting of a rectangular parallelepiped shape (a box like) member is connected. Further, to the side surface on the −X side of air floating device base 53 on the +X side and to the side surface on the +X side of air floating device base 53 on the −X side, respectively, a connecting member 53b consisting of a tabular member parallel to the XY plane is connected. Of the four interlinking members 52, for example, air floating device base 53 on the +X side is mounted, via connecting member 53a and connecting member 53b on the two interlinking members 52 on the +X side. Similarly, of the four interlinking members 52, for example, air floating device base 53 on the −X side is mounted, via connecting member 53a and connecting member 53b on the two interlinking members 52 on the −X side.

As shown in FIG. 6, to the vicinity of the edge on each of the +Y side and −Y side of the lower surface of air floating device base 53, a Y slider 55 is fixed via a spacer 55a. Y slider 55 consists of a member whose XZ section is an inverted U-shape, includes a plurality of balls that are not illustrated, and engages slidable with low friction with Y linear guides 44. Although it is not illustrated in FIG. 5 because the sliders overlap in the depth of the page surface, for example, two Y sliders 55 are provided near the edge on the +Y side and −Y side of each of the lower surfaces of the one pair of the air floating device bases 53 corresponding to Y linear guide 44.

Further, to each of the lower surfaces of the one pair of the air floating device bases 53, a Y mover 58 that faces Y stator 48 via a predetermined clearance (space/gap) is fixed (Y mover 58 fixed to air floating device base 53 on the −X side is not illustrated). Y mover 58 has a coil unit including a coil which is not illustrated, and configures a Y linear motor that drives Y step guide 50 in predetermined strokes along with Y stator 48 described above in the Y-axis direction. Further, although it is not illustrated, a Y linear scale whose periodic direction is in the Y-axis direction is fixed to base surface plate 40, and to Y step guide 50, a Y encoder head that configures a Y linear encoder system which obtains Y positional information of Y step guide 50 with the Y linear scale is fixed. Incidentally, Y mover 58 can be attached to X beam 51 instead of air floating device base 53.

Now, in a state where Y step surface plate 20 shown in FIG. 2 and Y step guide 50 are combined, X beam 21 on the +Y side of Y step surface plate 20 is inserted in between X beam 51 on the +Y side of Y step guide 50 and air floating device base 53, and X beam 21 on the −Y side of Y step surface plate 20 is inserted in between X beam 51 on the −Y side of Y step guide 50 and air floating device base 53 (refer to FIG. 1).

Further, in a state where Y step surface plate 20 shown in FIG. 2 and Y step guide 50 are combined, the two interlinking members 22 placed in the mid section in the longitudinal direction of the pair of X beams 21 of Y step surface plate 20 described above is placed above connecting member 53b. Further, X beam 21 of Y step surface plate 20 is placed above the plurality of interlinking members 52 of Y step guide 50 (refer to FIG. 1). Accordingly, Y step surface plate 20 (and device main section 30 which supports Y step surface plate 20) and Y step guide 50 (and the pair of base surface plate 40 which supports Y step guide 50) are distanced apart except for a part connected by a plurality of flexure devices 18 which will be described later on.

As shown in FIG. 2, Y step surface plate 20 and Y step guide 50 are mechanically connected to each other, for example, by a plurality of, e.g., four, flexure devices 18. For example, of the four flexure devices 18, two are laid across in between X beam 21 on the +Y side of Y step surface plate 20 and connecting member 53a of Y step guide 50. Further, for example, of the four flexure devices 18, the other two are laid across in between X beam 21 on the −Y side of Y step surface plate 20 and connecting member 53a with Y step guide 50. Incidentally, the number of flexure devices 18 and their arrangement is not limited to the ones described above, and can be appropriately changed.

The configuration of, for example, four flexure devices 18 is substantially the same. Each flexure device 18 includes a thin steel sheet (e.g., a flat spring) placed parallel to the XY plane, and connects X beam 21 and connecting member 53a via a frictionless joint device such as ball joints. Flexure device 18 connects Y step surface plate 20 and Y step guide 50 in the Y-axis direction with high rigidity by the rigidity of the steel sheet in the Y-axis direction. Accordingly, Y step surface plate 20 moves in the Y-axis direction integrally with Y step guide 50, by being pulled by Y step guide 50. On the contrary, because flexure device 18 does not restrict Y step surface plate 20 to Y step guide 50 in directions of five degree of freedom (each direction in the X-axis, the Z-axis, θx, θy, and θz) excluding the Y-axis direction due to the flexibility (or flexibleness) of the steel plate and the operation of the frictionless joint device, vibration hardly travels in the directions of five degrees of freedom described above between Y step surface plate 20 and Y step guide 50. Incidentally, as flexure device 18, a wire rope, a rope made of rigid resin and the like can also be used instead of the steel sheet described above, as long as the rigidity in the Y axis direction is secured and the device has flexibility mainly in the Z-axis direction. A configuration of flexure device 18 using a steel sheet is disclosed in, for example, U.S. Patent Application Publication No. 2010/0018950.

Referring back to FIG. 5, on the upper surface of each of the pair of air floating device bases 53, a plurality of, e.g., ten, air floating devices 59 are mounted. For example, each of the ten air floating devices is substantially the same, except for the point that their placement is different. For example, the upper surfaces of the ten air floating devices 59 form a substrate supporting surface which is substantially parallel to a horizontal plane rectangle in a planar view whose longitudinal direction is in the X-axis direction. While the length (dimension) in the X-axis direction and the length (dimension) in the Y-axis direction of the substrate support surface are set slightly shorter than the length (dimension) in the X-axis direction and the length (dimension) in the Y-axis direction of substrate P as shown in FIG. 2, the dimensions are set so that the entire lower surface of substrate P can be supported from below.

As shown in FIG. 5, air floating device 59 consists of a rectangular parallelepiped member whose longitudinal direction is in the X-axis direction. Air floating device 59 has a porous member on the upper surface (a surface facing the lower surface of substrate P), and substrate P is made to float by blowing out pressurized gas (e.g., air) from a plurality of fine pores that the porous member has to the lower surface of substrate P. The pressurized gas can be supplied to air floating device 59 from the outside, or a blower and the like can be built in air floating device 59 (or in air floating device base 53). Further, the pores for blowing out pressurized gas can be formed by mechanical processing. The floating amount of substrate P by the plurality of air floating device 59 (distance between the upper surface of air floating device 59 and the lower surface of substrate P) is set to around tens of micrometers to thousands of micrometers.

Of the pair of X carriages 70, one is mounted on X beam 51 on the +Y side, and the other is mounted on X beam 51 on the −Y side. The pair of X carriage 70 each consist of a plate shaped member placed parallel to the XY plane that have a rectangular shape in a planar view and whose longitudinal direction is in the X-axis direction, and as shown in FIG. 6, to the lower surface near the four corners, an X slider 76 is fixed (of the four sliders 76, 2 are hidden behind the other two in the depth of the page surface). X slider 76 consists of a member whose YZ section is an inverted U-shape, includes a plurality of balls that are not illustrated, and engages slidable with low friction with X linear guides 56.

Further, to each of the lower surfaces of the pair of opposing surfaces of X carriage 70, a X mover 77, which faces X stator 57 via a predetermined clearance (space/gap), is fixed. X mover 77 includes a coil unit which is not illustrated, and configures an X linear motor that drives X carriage 70 in predetermined strokes along with X stator 57 in the X-axis direction. Incidentally, although it is not illustrated, an X linear scale whose periodic direction is in the X-axis direction is fixed to each of the pair of X beams 51, and an X encoder head configuring an X linear encoder system to obtain the X positional information of X carriage 70 along with X linear scale described above is fixed to each of the pair of X carriages 70. The pair of X carriages 70 are each synchronously driven via the X linear motors by a main controller which is not illustrated, based on measurement values of the X linear encoder system.

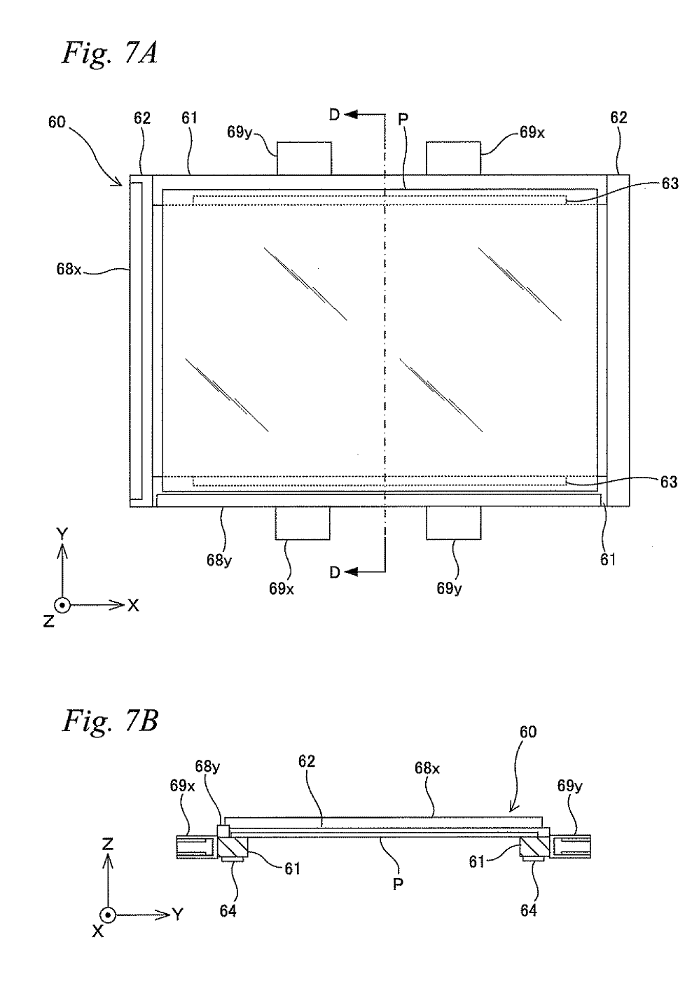

As shown in FIG. 7A, substrate support member 60 consists of a frame shaped member which is a rectangle in a planar view. Substrate support member 60 includes a pair of support members 61, and a pair of interlinking members 62 which integrally connect the pair of X support members 61. The pair of X support members 61 each consist of a bar-shaped member whose YZ sectional shape is rectangular (refer to FIG. 7B) extending in the X-axis direction, and the members are placed parallel to each other at a predetermined distance (a distance somewhat shorter than the dimension of substrate P in the Y-axis direction) in the Y-axis direction. The dimension in the longitudinal direction of each of the pair of X support members 61 is set slightly longer than the dimension of substrate P in the X-axis direction. Substrate P is supported from below by the pair of X support members 61, close to the edge on the +Y side and the −Y side.

The pair of X support members 61 each have an adsorption pad 63 on its upper surface. The pair of X support members 61 suction and hold the vicinity of both ends in the Y-axis direction of substrate P from below using adsorption pad 63, for example, by vacuum chucking. The pair of interlinking members 62 are each made up of a bar-shaped member whose XZ sectional shape is rectangular and longitudinal direction is on the Y-axis direction. One of the pair of interlinking members 62 is mounted on the upper surface of the pair of X support members 61 in the vicinity of the edge on the +X side of the pair of X support members 61, and the other is mounted on the upper surface of the pair of X support members 61 in the vicinity of the edge on the −X side of the pair of X support members 61. To the upper surface of support member 61 which is on the −Y side, a Y movable mirror 68y (a bar mirror) having a reflection surface orthogonal to the Y-axis is attached. Further, to the upper surface of interlinking member 62 on the −X side, an X movable mirror 68x (a bar mirror) having a reflection surface which is orthogonal to the X-axis is attached.

As shown in FIG. 2, the distance between the pair of X support members 61 in the Y-axis direction corresponds to the pair of X guides 24 of Y step surface plate 20. To the lower surface of each of the pair of X support members 61, air bearings 64 whose bearing surfaces face the upper surface of X guides 24 (refer to FIG. 4) are attached, as shown in FIG. 7B. Substrate support member 60 is supported by levitation on the pair of X guides 24 by the operation of air bearing 64 (refer to FIG. 1), and Y step surface plate 20 functions as a surface plate when substrate support member 60 moves in the X-axis direction.

As shown in FIG. 2, substrate support member 60 is driven in the X-axis, the Y-axis, and the θz directions with respect to the pair of X carriages 70, by two X voice coil motors 29x and two Y voice coil motors 29y. One of the two X voice coil motors 29x and one of the two Y voice coil motors 29y are placed on the −Y side of substrate support member 60, and the other of the two X voice coil motors 29x and the other of the two Y voice coil motors 29y are placed on the +Y side of substrate support member 60. One and other X voice coil motors 29x are placed at positions which are symmetric to each other with respect to center of gravity CG of a system that combines substrate support member 60 and substrate P, and one and other y voice coil motors 29y are placed at positions which are symmetric to each other with respect to center of gravity CG described above.

As shown in FIG. 2, X voice coil motor 29x includes an X stator 79x (refer to FIGS. 5 and 6) fixed to the upper surface of X carriage 70 via support member 78, and an X mover 69x (refer to FIGS. 7A and 7B) on the side surface of X support member 61. Further, Y voice coil motor 29y includes a Y stator 79y (refer to FIGS. 5 and 6) fixed to the upper surface of X carriage 70 via support member 78, and a Y mover 69y (refer to FIGS. 7A and 7B) on the side surface of X support member 61. X stator 79x and Y stator 79y each have, for example, a coil unit including a coil, and X mover 69x and Y mover 69y each have, for example, a magnet unit including a permanent magnet.

When each of the pair of X carriages 70 is driven in predetermined strokes in the X-axis direction, substrate support member 60 is synchronously driven (driven in the same direction and same speed as the pair of X carriages 70) with respect to the pair of X carriages 70 by the two X voice coil motors 29x. This allows the pair of X carriages 70 and substrate support member 60 to integrally move in the X-axis direction. Further, when Y step guide 50 is driven in predetermined strokes in the Y-axis direction, substrate support member 60 is synchronously driven (driven in the same direction and same speed as the pair of X carriages 70) with respect to the pair of X carriages 70 by the two Y voice coil motors 29y. This allows Y step guide 50 (and Y step surface plate 20) and substrate support member 60 to integrally move in the Y-axis direction. Further, when substrate support member 60 moves in long strokes in the X-axis direction along with the pair of X carriages 70, substrate support member 60 is finely driven appropriately in a direction around an axis parallel to the Z-axis passing through center of gravity CG, by the thrust difference of the two X voice coil motors 29x (or the two Y voice coil motors 29y).

Positional information in the XY plane of substrate support member 60 is obtained by a substrate interferometer system including X interferometer 66x and Y interferometer 66y, as shown in FIG. 2. X interferometer 66x is fixed to the pair of side columns 32 via interferometer support member 36. Y interferometer 66y is fixed to side column 32 on the −Y side. X interferometer 66x splits light from a light source which is not illustrated using a beam splitter which is not illustrated, irradiates the split light as a pair of X measurement beams parallel to the X-axis on X movable mirror 68x and also irradiates the split light as a reference beam on a fixed mirror (not illustrated) attached to projection optical system PL (or a member which can be regarded integral with projection optical system PL), respectively, overlays the reflected light from X movable mirror 68x of the measurement beam and the reflected light from the fixed mirror of the reference beam again and makes the beams enter a light receiving element which is not illustrated, and obtains the position of the reflection surface of X movable mirror 68x with the position of the reflection surface of the fixed mirror serving as a reference, based on the interference of the beams.

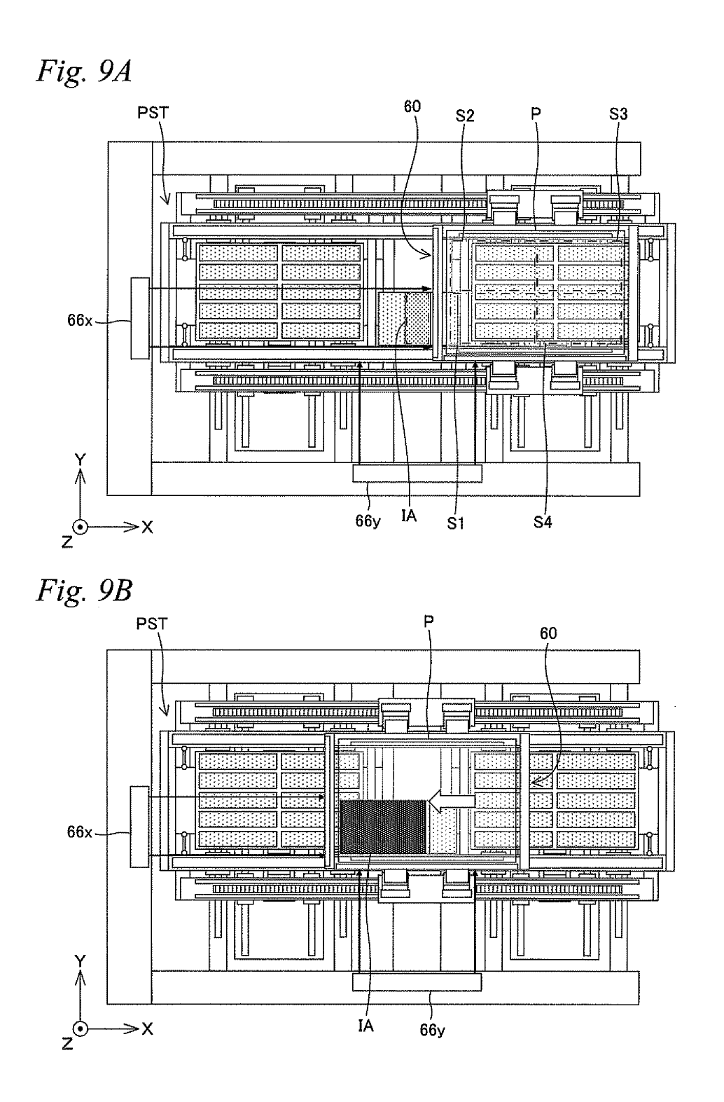

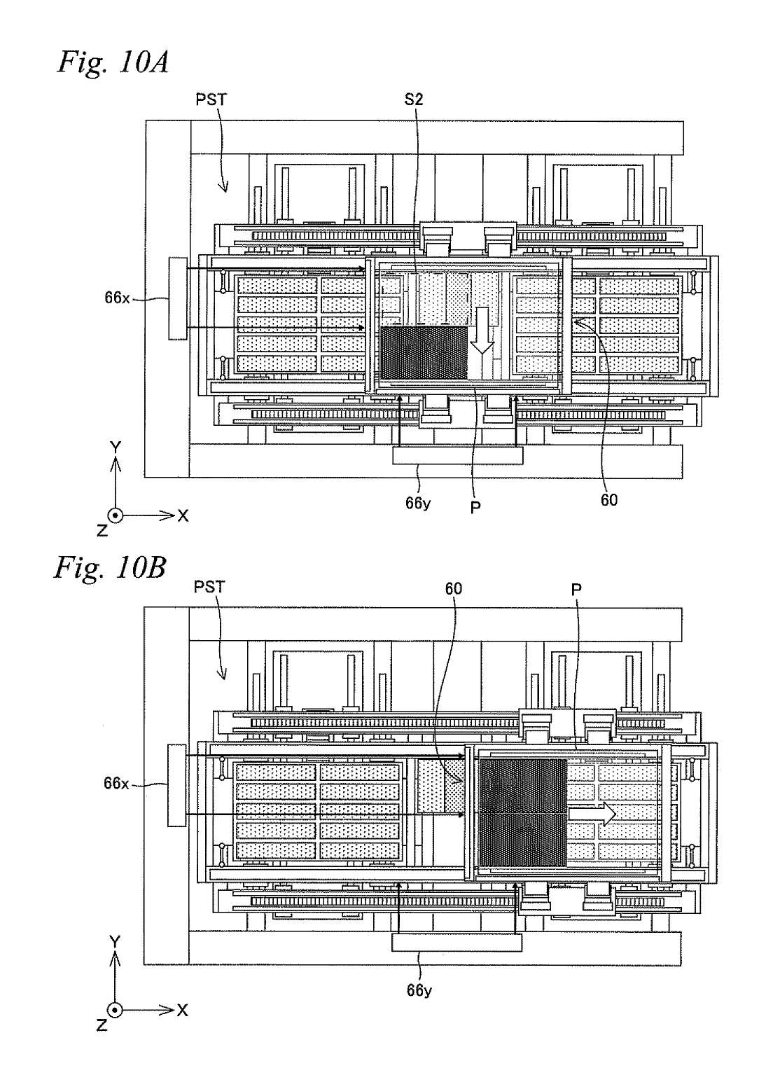

Y interferometer 66y similarly irradiates a pair of Y measurement beams parallel to the Y-axis on Y movable mirror 68y, as well as irradiates a reference beam on a fixed mirror which is not illustrated, and obtains the movement amount of substrate support member 60 in the Y-axis direction based on the reflected lights. In this case, the distance between the pair of Y measurement beams is set (refer to FIGS. 9A to 10B) so that at least one of the Y measurement beams irradiated from Y interferometer 66y is constantly irradiated on Y movable mirror 68y within a movable range of substrate support member 60 in the X-axis direction. Further, the distance between the pair of X measurement beams is set so that at least one of the X measurement beams irradiated from X interferometer 66x constantly irradiated on X movable mirror 68x within a movable range of substrate support member 60 in the Y-axis direction, and positional information of substrate support member 60, or in other words, positional information of substrate P in the θz direction is obtained by X interferometer 66x.

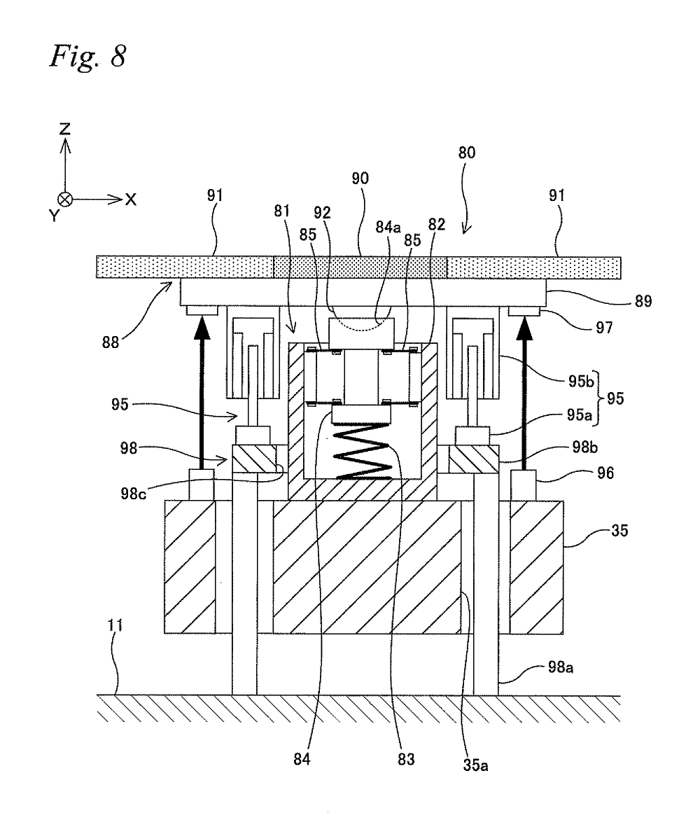

Fixed point stage 80 is mounted on fixed point stage mounting 35 as shown in FIG. 3, and in a state where Y step surface plate 20 and Y step guide 50 are combined as shown in FIG. 2, fixed point stage 80 is placed between the pair of air floating device base 53. Incidentally, in FIG. 4, from the viewpoint of avoiding intricacy of the drawings, in FIG. 4, illustration of fixed point stage 80 is omitted. As shown in FIG. 8, fixed point stage 80 is equipped with a weight cancellation device 81 mounted on fixed point stage mounting 35, an air chuck device 88 supported by weight cancellation device 81 from below, a plurality of Z voice coil motors 95 that drive air chuck device 88 in θx, θy, and Z-axis directions, in directions of three degrees of freedom and the like.

In this case, when Y step surface plate 50 (refer to FIG. 2) moves in the Y-axis direction in predetermined strokes, the dimension between the pair of X beams 51 (and/or the outer dimension of weight cancellation device 81) are set so as to keep the pair of X beams 51 and fixed point stage 80 from coming into contact.

Weight cancellation device 81 is equipped with a housing 82 fixed to fixed point stage mounting 35, a compression coil spring 83 housed in housing 82 that can expand and contract in the Z-axis direction, a Z slider 84 mounted on compression coil spring 83 and the like. Housing 82 is made up of a cylinder-like member having a bottom which is opened on the +Z side. Z slider 84 consists of a cylinder-like member that extends in the Z-axis, and is connected to an inner wall surface of housing 82 via a parallel plate spring device 85 including a pair of plate springs that are parallel to the XY plane and are placed apart in the Z-axis direction. Parallel plate spring device 85 is placed on the +X side, the −X side, the +Y side, and the −Y side of Z slider 84 (parallel plate spring devices 85 on the +Y side and the −Y side are not illustrated). While relative movement of Z slider 84 with respect to housing 82 in a direction parallel to the XY plane is restricted by the stiffness (extensional stiffness) of the plate springs that parallel plate spring devices 85 have, Z slider 84 is relatively movable with respect to housing 82 in the Z-axis direction with fine strokes due to the flexibility of the plate spring. The upper end (an end on the +Z side) of Z slider 84 projects out upward from the end on the +Z side of housing 82, and supports air chuck device 88 from below. Further, on the upper end surface of Z slider 84, a hemispherical recessed section 84a is formed.

Weight cancellation device 81 negates the weight (a force whose direction of gravitational force is downward (the −Z direction)) of substrate P, Z slider 84, air chuck device 88 and the like with an elastic force of compression coil spring 83 (a force whose direction of gravitational force is upward (the +Z direction)), which reduces the load of the plurality of Z voice coil motors 95. Incidentally, the weight of air chuck device 88 and the like can also be cancelled using a member whose load can be controlled as in an air spring like the weight cancellation device disclosed in, for example, U.S. Patent Application Publication No. 2010/0018950, instead of compression coil spring 83. Further, parallel plate spring device 85 can be of any number, as long as there is one set in the vertical direction.

Air chuck device 88 is located above (the +Z side) weight cancellation device 81. Air chuck device 88 has a base member 89, a vacuum preload air bearing 90 fixed on base member 89, and a pair of air floating devices 91 placed on each of the +X side and the −X side of vacuum preload air bearing 90.

Base member 89 consists of a plate shaped member which is placed parallel to the XY plane. To the center of the lower surface of base member 89, a spherical air bearing 92 having a bearing surface of a hemispheric shape is fixed. Spherical air bearing 92 is inserted into recess section 84a formed in Z slider 84. This allows air chuck device 88 to be swingably (freely rotatable in the θx and θy directions) supported by Z slider 84 with respect to the XY plane. Incidentally, as a device that swingably supports air chuck device 88 with respect to the XY plane, the device can be a pseudo-spherical bearing device using a plurality of air bearings as disclosed in, for example, U.S. Patent Application Publication No. 2010/0018950, or an elastic hinge device can be used.

As shown in FIG. 3, vacuum preload air bearing 90 consists of a rectangular plate shaped member in a planar view whose longitudinal direction is in the Y-axis direction, and its area is set slightly larger than exposure area IA. Vacuum preload air bearing 90 has a gas blow hole and a gas suction hole on the upper surface, and injects pressurized gas (e.g., air) from the gas blow hole toward the lower surface of substrate P (refer to FIG. 2), and also suctions the gas between the upper surface and substrate P from the gas suction hole. Vacuum preload air bearing 90 forms a gaseous film having high stiffness between its upper surface and the lower surface of substrate P by balancing the pressure of gas blown to the lower surface of substrate P and the negative pressure in between its upper surface and the lower surface of substrate P, and holds substrate P by suction in a non-contact manner via a substantially constant clearance (space/gap). Flow rate or pressure of the gas that is blown and the flow rate or pressure of the gas that is suctioned are set so that the distance between the upper surface (substrate holding surface) of vacuum preload air bearing 90 and the lower surface of substrate P is around the level, for example, from several micrometers to tens of micrometers.

Now, vacuum preload air bearing 90 is placed right below (the −Z side) projection optical system PL (refer to FIG. 1), and suctions and holds an area corresponding to exposure area IA of substrate P located right below projection optical system PL. Because vacuum preload air bearing 90 applies a so-called preload to substrate P, the stiffness of the gaseous film formed in between with substrate P can be increased, and even if substrate P was distorted or warped, the shape of the area of substrate P to be exposed which is located right under the projection optical system can be corrected without fail along the upper surface of vacuum preload air bearing 90. Further, because vacuum preload air bearing 90 does not restrict the position of substrate P in the XY plane, substrate P can perform relative movement with respect to illumination light IL (refer to FIG. 1) along the XY plane, even in a state when the area subject to exposure of substrate P is suctioned and held by vacuum preload air bearing 90. Details of such non-contact type air chuck devices (vacuum preload air bearing) are disclosed in, for example, U.S. Pat. No. 7,607,647 and the like. Incidentally, the pressurized gas blown from vacuum preload air bearing 90 can be supplied from outside, or a blower and the like can be incorporated in vacuum preload air bearing 90. Further, the suction device (vacuum device) which suctions the gas in between the upper surface of vacuum preload air bearing 90 and the lower surface of substrate P can be provided similarly outside of vacuum preload air bearing 90, or can be incorporated in vacuum preload air bearing 90. Further, the gas blow hole and the gas suction hole can be formed by mechanical processing, or a porous material can be used. Further, as a method of vacuum preload, negative pressure can be generated using only positive pressure gas (for example, as in a Bernoulli chuck device) without performing gas suction.

Similar to air floating device 59, each of the pair of air floating devices 91 blow pressurized air (e.g., air) to the lower surface of substrate P (refer to FIG. 2) from the upper surface. The Z position of the upper surface of the pair of air floating devices 91 is set substantially the same as the Z position on the upper surface of vacuum preload air bearing 90. Further, the Z position on the upper surface of vacuum preload air bearing 90 and the pair of air floating devices 91 is set at a position slightly higher than the Z position on the upper surface of the plurality of air floating devices 59. Therefore, as the plurality of air floating devices 59, a high floating type device which can make substrate P float higher when compared with the pair of air floating devices 91 is used. Incidentally, besides blowing pressurized gas toward substrate P, the pair of air floating devices 91 can also suction the air between its upper surface and substrate P similar to vacuum preload air bearing 90. In this case, it is desirable to set the suction force so that the load becomes weaker than the preload by vacuum preload air bearing 90.

The plurality of Z voice coil motors 95, as shown in FIG. 8, include a Z stator 95a fixed to a base frame 98 installed on floor 11, and a Z mover 95b which is fixed to base member 89. Z voice coil motors 95 are placed, for example, on the +X side, the −X side, the +Y side, and the −Y side of weight cancellation device 81 (Z voice coil motors 95 on the +Y side and the −Y side are not illustrated), and can finely drive air chuck device 88 in directions of three degrees of freedom, which are θx, θy, and the Z-axis. Incidentally, the plurality of Z voice coil motors 95 should be placed at least at three noncollinear positions.

Base frame 98 includes a plurality of (e.g., four, corresponding to Z voice coil motor 95) leg sections 98a inserted through each of a plurality of through holes 35a formed in fixed point stage mounting 35, and a main section 98b which is supported from below by the plurality of leg sections 98a. Main section 98b consists of a plate shaped member having an annular shape in a planar view, and into an opening 98c formed in the center, weight cancellation device 81 is inserted. The plurality of leg sections 98a are each in a non-contact state with fixed point stage mounting 35, and are vibrationally separated. Accordingly, the reaction force occurring when air chuck device 88 is driven using the plurality of Z voice coil motors 95 does not reach weight cancellation device 81.

Positional information of air chuck device 88 driven using the plurality of Z voice coil motors 95 in the directions of three degrees of freedom is obtained using a plurality of, e.g., four Z sensors 96 in the embodiment, fixed to fixed point stage mounting 35. One each of Z sensors 96 are placed on the +X side, the −X side, the +Y side, and the −Y side of weight cancellation device 81 (Z sensors on the +Y side and the −Y side are not illustrated). Z sensor 96 uses a target 97 fixed to the lower surface of base member 89 of air chuck device 88 to obtain variation in distance in the Z-axis direction of fixed point stage mounting 35 and base member 89. The main controller which is not illustrated constantly obtains positional information of air chuck device 88 in the Z-axis, θx, and θy directions based on the output of four Z sensors 96, and based on the measurement values, appropriately controls the four Z voice coil motors 95 so as to control the position of air chuck device 88. Because the plurality of Z sensors 96 and target 97 is placed in the vicinity of the plurality of Z voice coil motors 95, control at a high speed with high responsiveness becomes possible. Incidentally, the placement of Z sensors 96 and target 97 can be reversed.

Now, the ultimate position of air chuck device 88 is controlled so that the upper surface of substrate P passing above vacuum preload air bearing 90 is constantly located within the depth of focus of projection optical system PL. The main controller which is not illustrated drives and controls (autofocus control) air chuck device 88 so that the upper surface of substrate P is constantly located within the depth of focus of projection optical system PL (so that projection optical system PL always focuses on the upper surface of substrate P), while monitoring a position (surface position) on the upper surface of substrate P by a surface position measurement system (an autofocus sensor) which is not illustrated. Incidentally, because Z sensors 96 are required to obtain positional information of air chuck device 88 in the Z-axis, the θx, and the θy directions, for example, if the sensors are provided at three noncollinear positions, three sensors are acceptable.

In liquid crystal exposure apparatus 10 (refer to Fig.) which is configured as described above, loading of a mask on mask stage MST by a mask loader which is not illustrated, and loading of substrate P onto substrate support member 60 by a substrate loader which is not illustrated are performed under the control of the main controller which is not illustrated. After that, the main controller executes alignment measurement using an alignment detection system that is not illustrated, and after the alignment measurement has been completed, an exposure operation by the step-and-scan method is performed.

Now, an example of a movement of substrate stage device PST at the time of the exposure operation above will be described, based on FIGS. 9A to 10B. Incidentally, in the description below, while the case will be described where four shot areas are set on one substrate (the case when four dies are taken) is explained, the number of shot areas and the placement set on one substrate P can be appropriately changed.

As an example, as shown in FIG. 9A, the exposure processing is performed in the following order: a first shot area S1 set on the −Y side and the −X side of substrate P; a second shot area S2 set on the +Y side and the −X side of substrate P; a third shot area S3 set on the +Y side and the +X side of substrate P; and a fourth shot area S4 set on the −Y side and the +X side of substrate P. In substrate stage device PST, as shown in FIG. 9A, the position of substrate support member 60 in the XY plane is controlled based on the output of X interferometer 66x and Y interferometer 66y, so that the first shot area S1 is located on the +X side of exposure area IA.

Then, as shown in FIG. 9B, substrate support member 60 is driven (refer to the arrow in FIG. 9B) with respect to illumination light IL (refer to FIG. 1) in the −X direction at a predetermined constant speed based on the output of the pair of X interferometer 66x, and by this operation, a mask pattern is transferred on the first shot area S1 on substrate P. When exposure processing to the first shot area S1 is completed, as shown in FIG. 10A, substrate stage device PST controls (refer to the arrow in FIG. 10A) the position of substrate support member 60 in the XY plane based on the output of Y interferometer 66y, so that the edge on the +X side of the second shot area S2 is located slightly on the −X side of exposure area IA (not illustrated in FIG. 10A, refer to FIG. 2).

Subsequently, as shown in FIG. 108, substrate support member 60 is driven (refer to the arrow in FIG. 10B) with respect to illumination light IL (refer to FIG. 1) in the +X direction at a predetermined constant speed based on the output of X interferometer 66x, and by this operation, a mask pattern is transferred on the second shot area S2 on substrate P. Then, although it is not illustrated, the position of substrate support member 60 in the XY plane is controlled based on the output of X interferometer 66x, so that the edge on the −X side of the third shot area S3 (refer to FIG. 9A) is located slightly on the +X side of exposure area IA, and then substrate support member 60 is driven with respect to illumination light IL (refer to FIG. 1) in the −X direction at a predetermined constant speed based on the output of X interferometer 66x, and by this operation, a mask pattern is transferred on the third shot area S3 on substrate P. Subsequently, the position of substrate support member 60 in the XY plane is controlled based on the output of Y interferometer 66y, so that the edge on the +X side of the fourth shot area S4 (refer to FIG. 9A) is located slightly on the −X side of exposure area IA, and then substrate support member 60 is driven with respect to illumination light IL (refer to FIG. 1) in the +X direction at a predetermined constant speed based on the output of X interferometer 66x, and by this operation, a mask pattern is transferred on the fourth shot area S4 on substrate P.

While the exposure operation by the step-and-scan method described above is being performed, the main controller measures the surface position information of the area subject to exposure of the substrate P surface. Then, by controlling the position (surface position) in each of the Z-axis, the θx, and the θy directions of vacuum preload air bearing 90 that air chuck device 88 has based on the measurement values, the main controller positions the substrate P surface so that the surface position of the area subject to exposure located right under projection optical system PL is positioned within the depth of focus of projection optical system PL. This allows the surface position of the area subject to exposure to be positioned without fail within the depth of focus of projection optical system PL, even if, for example, the surface of substrate P was undulated or there was an error in the thickness of substrate P, and the exposure precision can be improved. Further, of substrate P, a large portion besides the area corresponding to exposure area IA is supported by levitation by the plurality of air floating devices 59. Accordingly, bending of substrate P due to its self-weight can be suppressed.

As described, because substrate stage device PST which liquid crystal exposure apparatus 10 related to the first embodiment has, performs pinpoint control of the surface position of the position corresponding to the exposure area on the substrate surface, the weight of the stage device can be largely reduced when compared with the case when a substrate holder (in other words, the entire substrate P) having an area about the same as substrate P is driven in the Z-axis direction and the tilt direction, respectively, like the stage device which is disclosed in, for example, U.S. Patent Application Publication No. 2010/0018950.

Further, because substrate support member 60 is configured to hold only the edges of substrate P, the X linear motor to drive substrate support member 60 requires only a small output, which can reduce running cost even if the size of substrate P increases. Further, it is easy to improve infrastructure such as power-supply facilities and the like. Further, because the X linear motor requires only a small output, initial cost can be reduced. Further, because the output (thrust) of the X linear motor is small, the influence (influence on exposure precision due to vibration) that the drive reaction force has on the overall system is also small. Further, assembly, adjustment, maintenance and the like are easy when compared with the conventional substrate stage device described above. Further, because the number of members are few and each of the members are light, carriage is also easy. Incidentally, while Y step guide 50 includes the plurality of air floating devices 59 and is large compared with substrate support member 60, because positioning of substrate P in the Z-axis direction is performed by fixed point stage 80 and air floating devices 59 in themselves only make substrate P float, stiffness is not required, which allows Y step guide 50 to be lightweight.

Further, because Y step surface plate 20 functioning as a surface plate (a guide member) when substrate support member 60 moves in the X-axis direction and Y step guide 50 including the pair of X carriages 70 to guide substrate support member 60 in the X-axis direction are vibrationally separated via flexure device 18 in directions of five degrees of freedom except for the Y-axis direction, the drive reaction force in the X-axis direction acting on Y step guide 50 when driving each of the pair of X carriages 70 using the X linear motor, and the vibration that occurs with the drive and the like do not travel to Y step surface plate 20. Accordingly, substrate support member 60 can be positioned with high accuracy in the X-axis direction.

Further, because the floating amount of substrate P by the plurality of air floating devices 59 is set to around tens of micrometers to thousands of micrometers (in other words, the floating amount is larger than fixed point stage 80), contact between substrate P and air floating devices 59 can be prevented even if substrate P is bent or the setting positions of air floating devices 59 have shifted. Further, because the stiffness of pressurized gas blowing out from the plurality air floating devices 59 is relatively low, the load of Z voice coil motors 95 when performing surface position control of substrate P using fixed point stage 80 is small.

Further, because the configuration of substrate support member 60 which supports substrate P is simple, the weight can be reduced. Further, while the reaction force when driving substrate support member 60 reaches Y step guide 50, because, with Y step guide 50 and device main section 30 (refer to FIG. 1) are not connected other than by flexure device 18, the risk of affecting the exposure apparatus is small even if device vibration (swaying of device main section 30, or resonance phenomena by vibrational excitation and the like) by the drive reaction force occurs.

Further, because the weight of Y step guide 50 is heavier than substrate support member 60, the drive reaction force is larger than when substrate support member 60 is driven, however, because Y step guide 50 and device main section 30 (refer to FIG. 1) are not connected other than by flexure device 18, the risk of the device vibration described above caused by the drive reaction force affecting the exposure apparatus is small.

Further, because Y step surface plate 20 and Y step guide 50 were connected (connected in a state without restricting each other in directions other than the Y-axis direction) by flexure device 18 having low rigidity in directions other than the Y-axis direction, even if the degree of parallelization between Y linear guide 38 guiding Y step surface plate 20 in the Y-axis direction and Y linear guide 44 guiding Y step guide 50 in the Y-axis direction decreases, the load acting on Y step surface plate 20 or Y step guide 50 due to the decrease in the degree of parallelization can be released.

### Second Embodiment

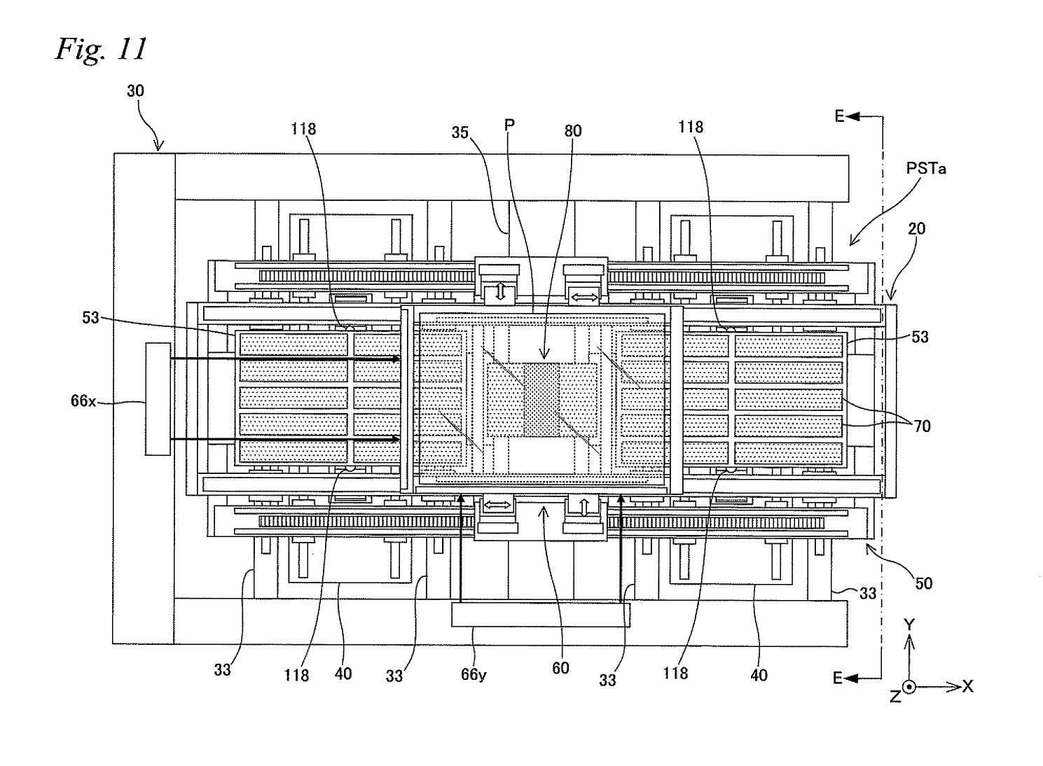

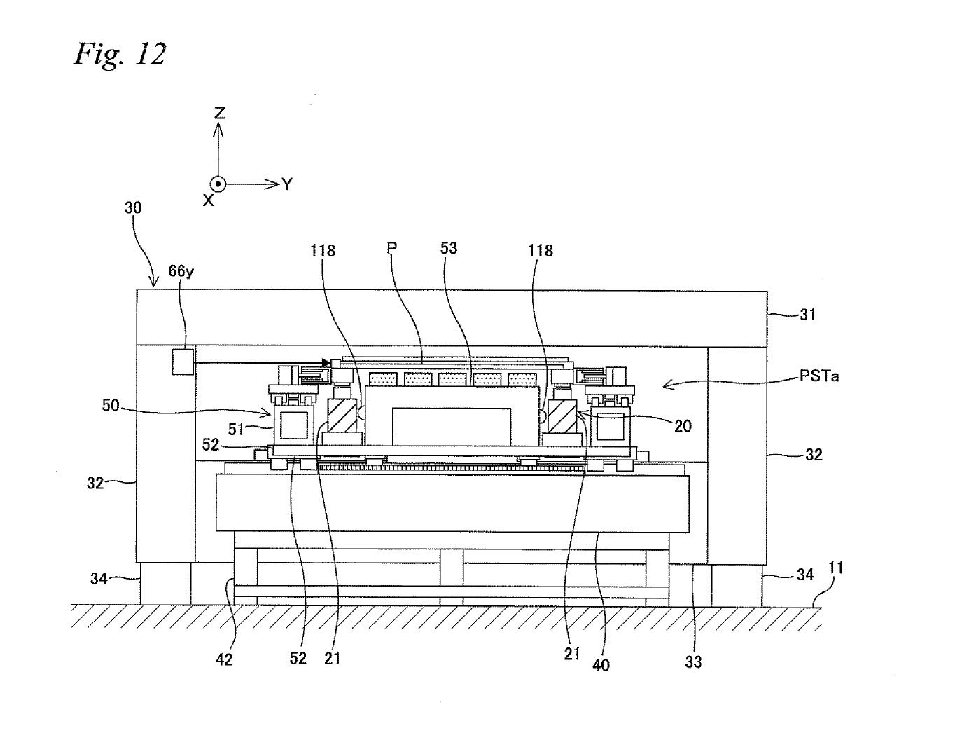

Next, a substrate stage device PSTa related to a second embodiment is described, based on FIGS. 11 and 12. Substrate stage device PSTa of the second embodiment differs from the first embodiment described above in the driving method of Y step surface plate 20. Incidentally, in the second embodiment (and other embodiments that will be described later on), for members that have the same configuration and the same function as substrate stage device PST (refer to FIG. 2) of the first embodiment, the same reference numerals will be used as in the first embodiment, and a description thereabout will be omitted.

In the first embodiment described above, while Y step surface plate 20 is towed by Y step guide 50 via the plurality of flexure devices 18 (refer to FIG. 2), in the second embodiment, Y step surface plate 20 moves in the Y-axis direction along with Y step guide 50 by being pushed to Y step guide 50 via a plurality of pusher devices 118 fixed to Y step guide 50.

Pusher device 118 is fixed to each of the pair of air floating device bases 53 on the +Y side surface and the −Y side surface, respectively, as shown in FIG. 11. Pusher device 118 includes a steel ball (a member having high hardness such as a ball formed by ceramics), and as shown in FIG. 12, the steel ball faces an inner surface (a surface on the −X side of X beam 21 on the +X side, and a surface on the +X side of X beam 21 on the −X side) of X beam 21 of Y step surface plate 20 via a predetermined clearance (space/gap). Incidentally, the number of pusher devices 118 and their arrangement is not limited to the ones described above, and can be appropriately changed.

In substrate stage device PSTa, when Y step guide 50 is driven in the Y-axis direction (the +Y direction or the −Y direction) on the pair of base surface plates 40 by a Y linear motor, pusher device 118 fixed to the side surface (the side surface on the +Y side, or the side surface on the −Y side) of air floating device base 53 comes into contact with X beam 21 of Y step surface plate 20. Then, Y step surface plate 20 moves integrally with Y step guide 50 in the Y-axis direction, by being pressed to Y step guide 50 via pusher device 118. Further, after Y step surface plate 20 has been moved in the Y-axis direction to the desired position, Y step guide 50 is finely driven in a direction opposite to the drive direction at the time of positioning described above so that pusher device 118 separates from X beam 21 of Y step surface plate 20.

In this state, because Y step surface plate 20 and Y step guide 50 are completely separated, vibration and the like caused by the reaction force that occurs, for example, when driving the pair of X carriages 70, can be prevented from traveling to Y step surface plate 20. Accordingly, when substrate support member 60 is driven in the Y-axis direction (or the θz direction) using a pair of Y voice coil motor 29y while substrate support member 60 is driven in long strokes in the X-axis direction during the exposure operation, vibration and the like occurring due to the reaction force acting on Y step guide 50 on the drive does not travel to Y step surface plate 20. Incidentally, a Y actuator which makes a steel ball finely move in the Y-axis direction can be provided in pusher device 118, and after the movement of Y step surface plate 20 described above, only the steel ball can be made to be separated from Y step surface plate 20. In this case, it is not necessary to move the entire Y step guide 50.

### Third Embodiment

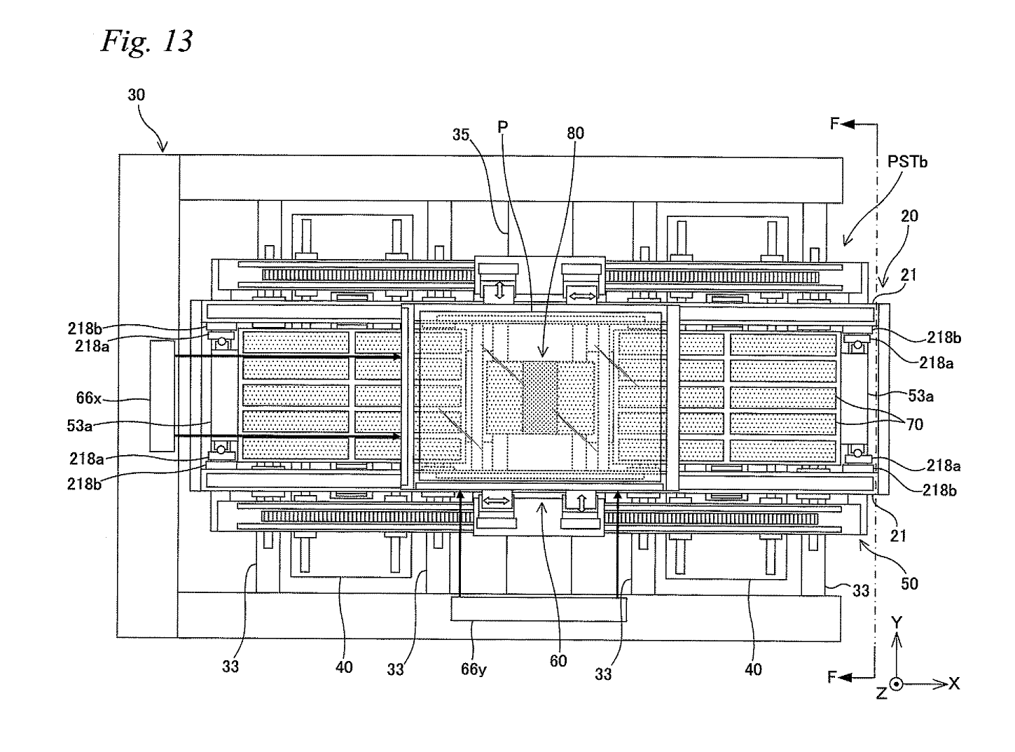

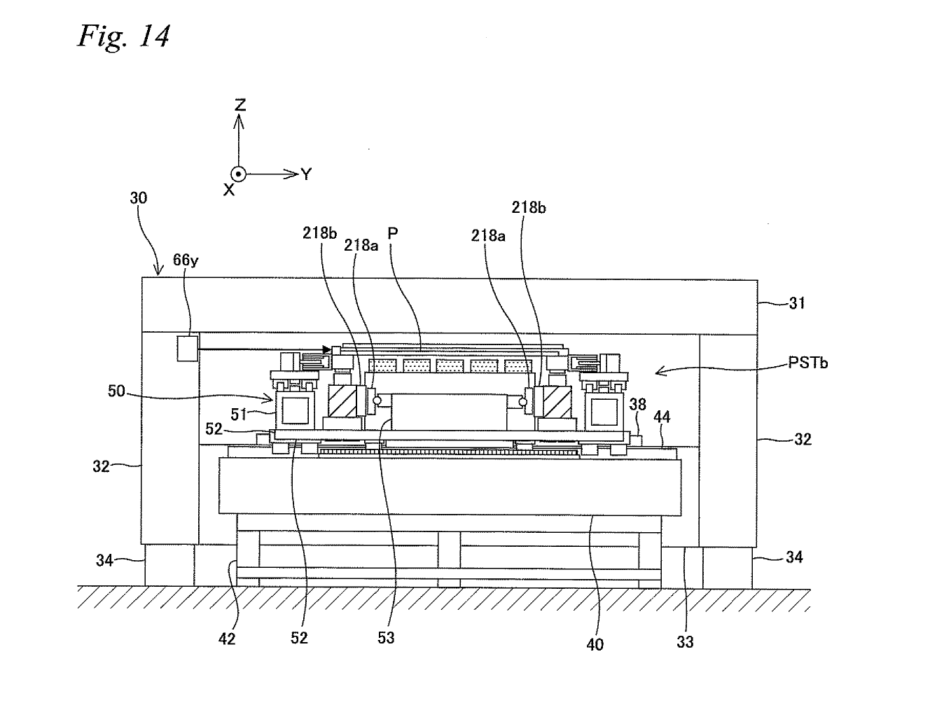

Next, a substrate stage device PSTa related to a second embodiment is described, based on FIGS. 13 and 14. Substrate stage device PSTb of the third embodiment differs from the first embodiment described above in the driving method of Y step surface plate 20. In substrate stage device PSTb of the third embodiment, Y step surface plate 20 moves in the Y-axis direction along with Y step guide 50 by being pushed to Y step guide 50 via a gaseous film formed by the plurality of air bearings 218a attached to Y step guide 50.

As shown in FIG. 13, air bearing 218a is attached to the side surface on the +Y side and the side surface on the −Y side of the pair of connecting devices 53a, respectively. Air bearing 218a includes a pad member which blows pressurized air (e.g., air) from the bearing surface, and ball joints and the like which swingably (finely rotatable in the θx and θz directions) supports the pad member and the like. To the inner side surface of X beam 21 of Y step surface plate 20, an opposing member 218b is fixed, consisting of a plate shaped member parallel to the XZ plane and facing the bearing surface of the pad member via a predetermined clearance (space/gap). Incidentally, the number and placement of air bearing 218a and opposing member 218b are not limited to the ones described above, and can be appropriately changed, such as, for example, air bearing 218a being attached to Y step surface plate 20, and opposing member 218b being attached to Y step guide 50.

In substrate stage device PSTb, when Y step guide 50 is driven in the Y-axis direction on a pair of base surface plates 40 by a Y linear motor, Y step surface plate 20 is pushed to Y step guide 50 in a non-contact state by static pressure (the rigidity of the gaseous film formed between the bearing surface of air bearing 218a and opposing member 218b), and moves integrally with Y step guide 50 in the Y-axis direction. Accordingly, Y step surface plate 20 and Y step guide 50 are vibrationally separated in directions of five degrees of freedom except for the Y-axis direction, and vibration and the like caused by the reaction force that occurs, for example, when driving the pair of X carriages 70, can be prevented from traveling to Y step surface plate 20, similar to the first embodiment. Further, because Y step surface plate 20 and Y step guide 50 are non-contact unlike the first embodiment, Y step surface plate 20 and Y step guide 50 can be vibrationally separated without fail in directions of five degrees of freedom except for the Y-axis direction. Further, because none of the members repeat contact and separation as in the second embodiment, shock generation or dust generation can be suppressed.

### Fourth Embodiment

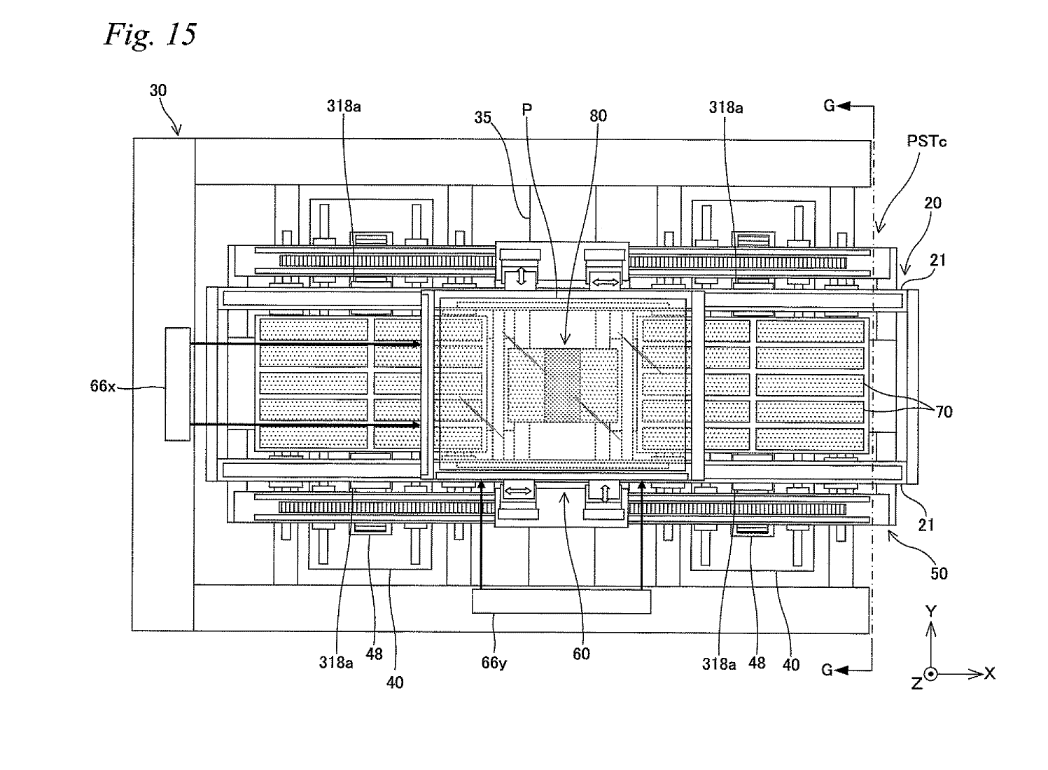

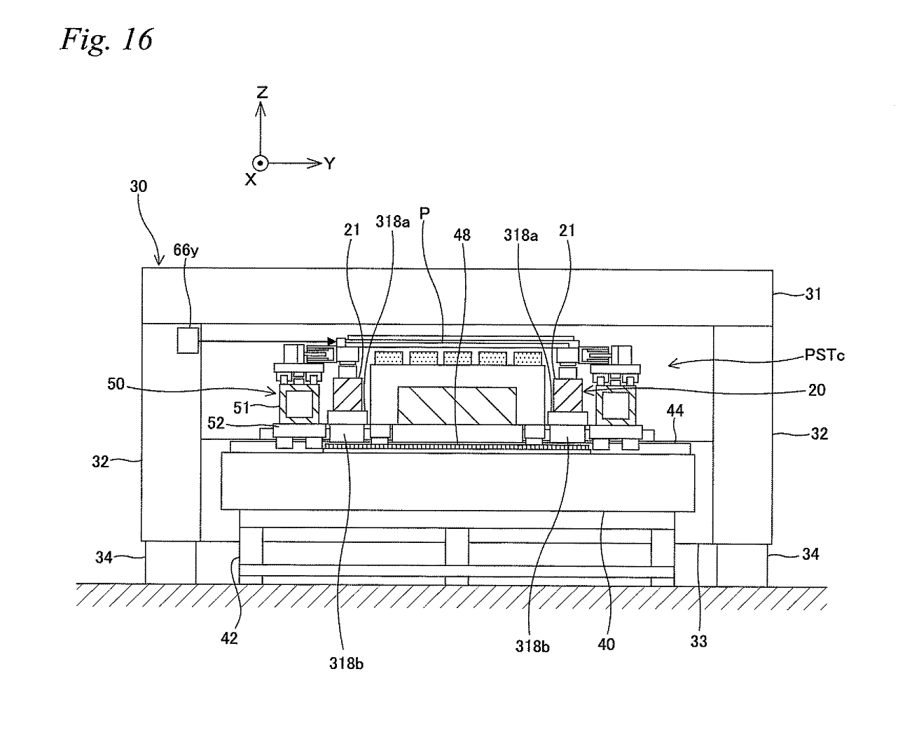

Next, a substrate stage device PSTc related to a fourth embodiment is described, based on FIGS. 15 and 16. Substrate stage device PSTc of the fourth embodiment differs from the first embodiment described above in the driving method of Y step surface plate 20. In substrate stage device PSTc of the fourth embodiment, Y step surface plate 20 is driven in the Y-axis direction independently from Y step guide 50 by a Y linear motor configured of a Y mover 318b (not illustrated in FIG. 15, refer to FIG. 16) fixed to the lower surface of X beam 21 via a spacer 318a, and a Y stator 48 fixed to base surface plate 40 (however, Y step surface plate 20 and Y step guide 50 are actually driven synchronously in the Y-axis direction). Incidentally, while substrate stage device PSTc shown in FIG. 16 is equivalent to the sectional view of line G-G in FIG. 15, lower column 33 (and Y linear guides 38 fixed to the upper surface of lower column 33) located outermost on the +X side (nearest when viewed from the +X side) is omitted for the sake of clarity of the configuration of substrate stage device PSTc.

Y mover 318b has a coil unit including a coil which is not illustrated, and for one X beam 21, two Y movers 318b are provided, spaced apart in the X-axis direction (refer to FIG. 15). Positional information of Y step surface plate 20 is obtained by a Y linear encoder system including a Y scale (common with a Y scale which configures a Y linear encoder system to obtain positional information of Y step guide 50) fixed to base surface plate 40, and a Y encoder head (Y scale and Y encoder head are not illustrated, respectively) fixed to Y step surface plate 20, and the Y position of Y step surface plate 20 is controlled, based on measurement values of the Y linear encoder system. Incidentally, in substrate stage device PSTc, while the dimension of Y stator 48 which configures the Y linear motor in the Y-axis direction is set longer than the first to third embodiments described above to drive Y step surface plate 20 in the Y-axis direction, the same reference code is used for the sake of convenience.

In substrate stage device PSTc, similar to the second embodiment described above, because Y step surface plate 20 and Y step guide 50 are completely separated, vibration and the like caused by the reaction force that occurs, for example, when driving the pair of X carriages 70, can be prevented from traveling to Y step surface plate 20. Accordingly, when substrate support member 60 is driven in the Y-axis direction (or the θz direction) using a pair of Y voice coil motor 29y while substrate support member 60 is driven in long strokes in the X-axis direction during the exposure operation, vibration and the like occurring due to the reaction force acting on Y step guide 50 on the drive does not travel to Y step surface plate 20. Incidentally, because Y stator 48 is fixed to base surface plate 40 while Y step surface plate 20 is mounted on device main section 30, the distance between Y stator 48 and Y mover 318b may change, therefore, it is desirable to use a coreless linear motor as the Y linear motor which drives Y step surface plate 20.

### Fifth Embodiment

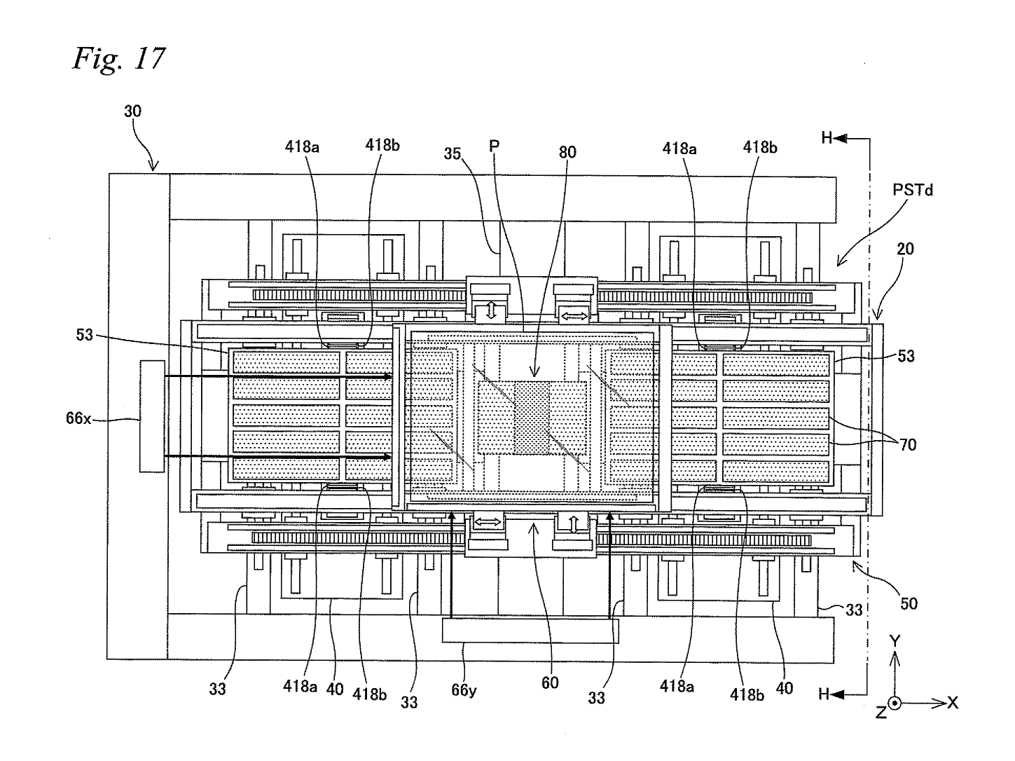

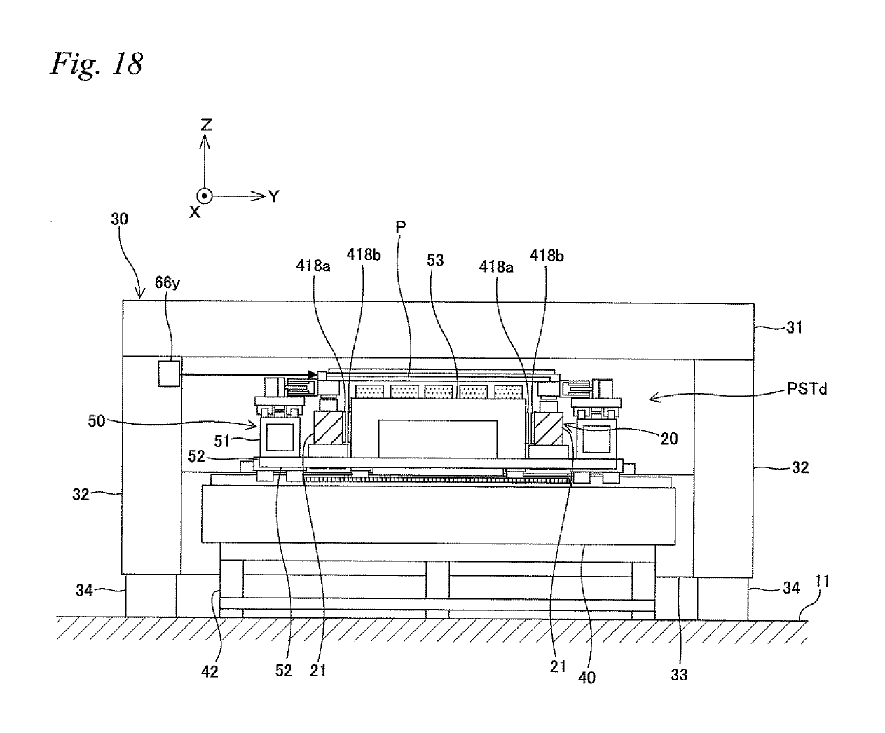

Next, a substrate stage device PSTd related to a fifth embodiment is described, based on FIGS. 17 and 18. Substrate stage device PSTd of the fifth embodiment differs from the first embodiment described above in the driving method of Y step surface plate 20. In substrate stage device PSTd of the fifth embodiment, Y step surface plate 20 moves in the Y-axis direction along with Y step guide 50 by being pressed by Y step guide 50 in a state (non-contact) with no mechanical contact by a repulsive force (repulsion) occurring between the plurality of permanent magnets 418a attached to Y step guide 50 and a plurality of permanent magnet 418b attached to Y step surface plate 20.

Permanent magnets 418a are fixed to each of the pair of air floating device bases 53 on the +Y side surface and the −Y side surface, respectively, as shown in FIG. 17. Further, permanent magnets 418b are fixed to the inner surface of X beam 21 of Y step surface plate 20, corresponding to the plurality of permanent magnets 418a. And, permanent magnet 418a and permanent magnet 418b are placed so that the polarity of opposing surfaces facing each other is the same (so that an S pole faces an S pole, or an N pole faces an N pole). Incidentally, the number of permanent magnets 418a and permanent magnets 418b and their arrangement are not limited to the ones described above, and can be appropriately changed.

In substrate stage device PSTd, when Y step guide 50 is driven on a pair of base surface plates 40 in the Y-axis direction by a Y linear motor, Y step surface plate 20 is pushed to Y step guide 50 and integrally moves in the Y-axis direction with the Y step guide 50 in a state where a predetermined clearance (space/gap) is formed between Y step surface plate 20 and Y step guide 50 (without being in contact mechanically) by a magnetic repulsive force generated between permanent magnets 418a and permanent magnets 418b that face each other. In substrate stage device PSTd related to the fifth embodiment, adding to a similar effect which can be obtained in the third embodiment described above, a predetermined clearance (space/gap) can be formed between Y step surface plate 20 and Y step guide 50 without supplying energy such as pressurized gas or electricity, which can simplify the configuration of the device. Further, there is no possibility of dust being raised, and vibration travelling.

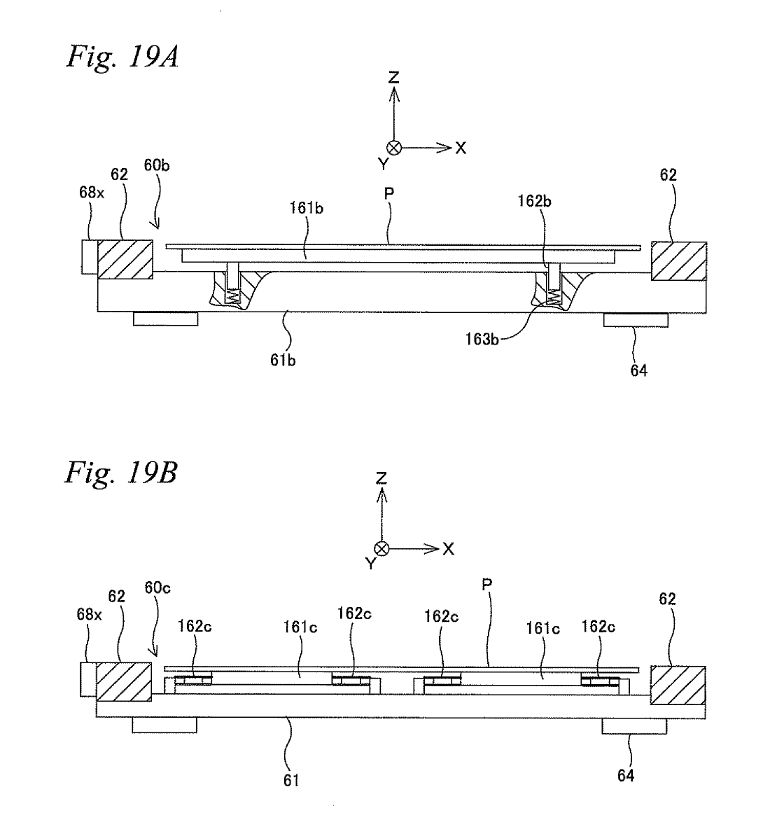

Incidentally, the configuration of the liquid crystal exposure apparatus including the substrate stage device, is not limited to the ones described in the embodiments above, and can be appropriately changed. For example, as shown in FIG. 19A, substrate support member 60b can hold substrate P by suction using a holding member 161b which is finely movable in the Z-axis direction with respect to X support member 61b. Holding member 161b consists of a bar-shaped member extending in the X-axis direction, and has adsorption pads (the piping for vacuum suction is not illustrated) which are not illustrated on its upper surface. In the vicinity of both ends in the longitudinal direction to each of the lower surface of holding member 161b, a pin 162b extruding downward (to the −Z side) is attached. Pin 162b is inserted into a recess section formed on the upper surface of X support member 61b, and is supported from below by a compression coil spring housed in the recess section. This allows holding member 161b (in other words, substrate 2) to move in the Z-axis direction (the vertical direction) with respect to X support member 61b. As previously described, in the first to fifth embodiment described above, because fixed point stage 80 is mounted on fixed point stage mounting 35 which is a part of device main section 30 as shown in FIG. 2 and Y step guide 50 is mounted on base surface plate 40 via a pair of mountings 42, the Z position (the Z position of the movement plane when substrate support member 60b moves parallel to the XY plane) of substrate support member 60b and the Z position of air floating device 59 may change, for example, due to the operation of vibration isolator 34, however, because substrate support member 60b shown in FIG. 19 A does not restrict substrate P in the Z-axis direction, even if the Z position of substrate support member 60b and the Z position of fixed point stage 80 shift, substrate P moves (vertically) in the Z-axis direction with respect to X support member 61b corresponding to the Z position of air floating device 59, which suppresses the load in the Z-axis direction with respect to substrate P. Incidentally, as in substrate support member 60c shown in FIG. 19B, a configuration in which a holding member 161c having adsorption pads which are not illustrated is finely movable in the Z-axis direction with respect to the X support member 61, using a plurality of parallel plate spring devices 162c can also be employed.

Further, while substrate support member 60 was configured so that substrate P was held by suction from below, besides this, the substrate can be held, for example, by a pressing device which presses (from one side of X support member 61 to the other side of X support member 61) the edge of substrate Pin the Y-axis direction. In this case, exposure processing can be performed on substantially the entire surface of substrate P.

Further, the single axis guide which guides Y step surface plate 20, Y step guide 50, or X carriage 70 straight, for example, can be a non-contact type single axis guide including a guide member made of a stone material, ceramics or the like, and a plurality of static gas bearings (air bearings).

Further, the drive device used to drive Y step surface plate 20, Y step guide 50, or X carriage 70 can be a feed screw device which is a combination of a ball screw and a rotary motor, a belt drive device which is a combination of a belt (or a rope) and a rotary motor, and the like.

Further, while substrate support member 60 was levitated on Y step surface plate 20 by static pressure of the pressurized gas blowing from air bearing 64, as well as this, for example, a gas suction function can be given to air bearing 64, and the gas between substrate support member 60 and X guide 24 can be suctioned so as to apply a preload to substrate support member 60, and the clearance (space/gap) between substrate support member 60 and X guide 24 can be narrowed to increase the rigidity of the gas between substrate support member 60 and X guide 24.

Further, positional information of substrate support member 60 can be obtained using a linear encoder system. Further, positional information of each of the pair of X support members 61 that substrate support member 60 has can be obtained independently using the linear encoder system, and in this case, the pair of X support members 61 do not have to be mechanically connected (interlinking member 62 will not be necessary).

Further, in fixed point stage 80 (refer to FIG. 8), in the case the drive reaction force of stator 95a of Z voice coil motor 95 which drives air chuck device 88 is small enough so that the influence on device main section 30 can be ignored, stator 95a can be fixed to fixed point stage mounting 35.

Further, in fixed point stage 80, air chuck device 88 can be configured movable in the X-axis direction, and before the scanning exposure operation begins, vacuum preload air bearing 90 can be positioned to be at the upstream side (for example, the +X side of exposure area IA before exposure of the first shot area S1, as shown in FIG. 9A) of the movement direction of substrate P where surface position adjustment of the upper surface of substrate P can be performed in advance, and then with substrate P moving in the scanning direction, air chuck device 88 can be synchronously moved with substrate P (substrate support member 60) (air chuck device 88 is to be stopped right under exposure area IA during exposure).

Further, as the method of moving Y step surface plate 20 by Y step guide 50, the drive method in the first to third embodiment and the fifth embodiment can be combined. For example, as in the first embodiment described above, flexure device 18 (refer to FIG. 2) and pusher device 118 (FIG. 11) can be used together, or pusher device 118 and the pair of permanent magnets 418a and 418b (FIG. 17) can be used together to move Y step surface plate 20 by Y step guide 50.

Further, a counter mass can be provided, to reduce the drive reaction force in the case of driving a movable member such as the pair of X carriages 70 or Y step guide 50 (and Y step surface plate 20 in the fourth embodiment) using a linear motor.

Further, the illumination light can be an ultraviolet light such as an ArF excimer laser light (with a wavelength of 193 nm), or a KrF excimer laser light (with a wavelength of 248 nm), or a vacuum ultraviolet light such as an F2 laser light (with a wavelength of 157 nm). Further, as the illumination light, a harmonic wave, which is obtained by amplifying a single-wavelength laser light in the infrared or visible range emitted by a DFB semiconductor laser or fiber laser with a fiber amplifier doped with, for example, erbium (or both erbium and ytterbium), and by converting the wavelength into ultraviolet light using a nonlinear optical crystal, can also be used. Further, solid state laser (with a wavelength of 355 nm, 266 nm) or the like can also be used.

Further, while, in each of the embodiments described above, the case has been described where projection optical system PL is the projection optical system by a multi-lens method that is equipped with a plurality of projection optical units, the number of the projection optical units is not limited thereto, but there should be one or more projection optical units. Further, the projection optical system is not limited to the projection optical system by a multi-lens method, but can be a projection optical system using, for example, a large mirror of the Offner type, or the like.

Further, while the case has been described where the projection optical system whose projection magnification is equal magnification is used as projection optical system PL in each of the embodiment described above, as well as this, the projection optical system can be either of a reduction system or a magnifying system.

Incidentally, in each of the embodiments above, alight transmissive type mask is used, which is obtained by forming a predetermined light-shielding pattern (or a phase pattern or a light-attenuation pattern) on a light transmissive mask substrate. Instead of this mask, however, as disclosed in, for example, U.S. Pat. No. 6,778,257, an electron mask (a variable shaped mask) on which a light-transmitting pattern, a reflection pattern, or an emission pattern is formed according to electronic data of the pattern that is to be exposed, for example, a variable shaped mask that uses a DMD (Digital Micromirror Device) that is a type of a non-emission type image display element (which is also called a spatial light modulator) can also be used.

Incidentally, it is particularly effective to apply the exposure apparatus to an exposure apparatus which exposes a substrate whose size (including at least one of the external diameter, diagonal line, and one side) is 500 mm or more, such as, for example, a large substrate of a flat panel display (FPD) such as the liquid crystal display and the like.

Further, the exposure apparatus can also be adapted also to a step-and-repeat type exposure apparatus, and a step-and-stitch type exposure apparatus.

Further, the application of the exposure apparatus is not limited to the exposure apparatus for liquid crystal display elements in which a liquid crystal display element pattern is transferred onto a rectangular glass plate, but each of the embodiments above can also be widely applied, for example, to an exposure apparatus for manufacturing semiconductors, and an exposure apparatus for producing thin-film magnetic heads, micromachines, DNA chips, and the like. Further, each of the embodiments above can be applied not only to an exposure apparatus for producing microdevices such as semiconductor devices, but can also be applied to an exposure apparatus that transfers a circuit pattern onto a glass plate or silicon wafer to produce a mask or a reticle used in a light exposure apparatus, an EUV exposure apparatus, an X-ray exposure apparatus, an electron-beam exposure apparatus, and the like. Incidentally, an object that is subject to exposure is not limited to a glass plate, but for example, can be another object such as a wafer, a ceramic substrate, a film member or a mask blank. Further, in the case where an exposure subject is a substrate for flat-panel display, the thickness of the substrate is not limited in particular, and for example, a film like member (a sheet like member having flexibility) is also included.

Further, the movable body apparatus (stage device) which moves an object along a predetermined two-dimensional plane is not limited to an exposure apparatus, and can also be applied to an object processing device and the like that performs a predetermined processing on an object, such as in an object inspection equipment used for inspection of the object.

Incidentally, the disclosures of the U.S. patent application Publications and the U.S. patents that are cited in the description so far related to exposure apparatuses and the like are each incorporated herein by reference.

Device Manufacturing Method

A manufacturing method of a microdevice that uses the exposure apparatus related to each of the embodiments above in a lithography process is described next.

In the exposure apparatus concerning each embodiment described above, liquid crystal display as the micro device can be obtained by forming a predetermined pattern (a circuit pattern, an electrode pattern) on a plate (a glass substrate).

Pattern Forming Process

First of all, a so-called optical lithography process in which a pattern image is formed on a photosensitive substrate (such as a glass substrate coated with a resist) is executed using the exposure apparatus related to each of the embodiments above described above. In this optical lithography process, a predetermined pattern that includes many electrodes and the like is formed on the photosensitive substrate. After that, the exposed substrate undergoes the respective processes such as a development process, an etching process and a resist removing process, and thereby the predetermined pattern is formed on the substrate.

Color Filter Forming Process

Next, a color filter in which many sets of three dots corresponding to R (Red), G (Green) and B (blue) are disposed in a matrix shape, or a color filter in which a plurality of sets of filters of three stripes of R, G and B are disposed in horizontal scanning line directions is formed.

Cell Assembling Process

Next, a liquid crystal panel (a liquid crystal cell) is assembled using the substrate having the predetermined pattern obtained in the pattern forming process, the color filter obtained in the color filter forming process, and the like. For example, a liquid crystal panel (a liquid crystal cell) is manufacture by injecting liquid crystal between the substrate having the predetermined pattern obtained in the pattern forming process and the color filter obtained in the color filter forming process.

Module Assembling Process

After that, a liquid crystal display element is completed by attaching respective components such as an electric circuit that causes a display operation of the assembled liquid crystal panel (liquid crystal cell) to be performed, and a backlight. In this case, since exposure of the substrate is performed with high throughput and high precision using the exposure apparatus related to each of the embodiments described above in the pattern forming process, the productivity of liquid crystal display elements can be improved as a consequence.

While each of the above-described embodiments of the present invention is the presently preferred embodiment thereof, those skilled in the art of lithography systems will readily recognize that numerous additions, modifications, and substitutions may be made to the above-described embodiments without departing from the spirit and scope thereof. It is intended that all such modifications, additions, and substitutions fall within the scope of the present invention, which is best defined by the claims appended below.

1. A movable body apparatus, comprising:
a first movable body which holds an edge of an object placed along a predetermined two-dimensional plane that is parallel to a horizontal plane, and is movable with predetermined strokes at least in a first direction within the two-dimensional plane;
a second movable body which includes an object support member that supports the object from below within a movable range in the first direction of the first movable body, and is movable in a second direction orthogonal to the first direction within the two-dimensional plane along with the first movable body; and
a third movable body which is vibrationally separated from the object support member at least in the first direction, supports the first movable body from below within a movable range of the first movable body in the first direction, and is movable along with the second movable body in the second direction.

2. The movable body apparatus according to claim 1 wherein
the second movable body moves in the second direction on a first base member, and
the third movable body moves in the second direction on a second base member which is vibrationally separated from the first base member.

3. The movable body apparatus according to claim 1 wherein
the first movable body is supported in a non-contact manner on the third movable body.

4. The movable body apparatus according to claim 1 the apparatus further comprising:
a fourth movable body which is movable in the first direction on the second movable body, and
the first movable body moves in the first direction by being induced by the fourth movable body.

5. The movable body apparatus according to claim 4 wherein
when the fourth movable body is driven in the first direction, the first movable body is driven synchronously with the fourth movable body by a first linear motor including a stator provided in the fourth movable body and a mover provided in the first movable body.

6. The movable body apparatus according to claim 4 wherein
when the fourth movable body is driven in the first direction, the first movable body is finely driven in at least one of the second direction and a direction around an axis orthogonal to the two dimensional plane by a second linear motor including a stator provided in the fourth movable body and a mover provided in the first movable body.

7. The movable body apparatus according to claim 1 wherein
the second movable body is driven in the second direction by a drive device,
the second movable body and the third movable body are connected by an interlinking device, and
the third movable body moves in the second direction with the second movable body by being pulled via the interlinking device by the second movable body.

8. The movable body apparatus according to claim 7 wherein
of directions of six degrees of freedom, rigidity of the interlinking device in directions of five degrees of freedom that excludes the second direction is lower than the rigidity in the second direction.

9. The movable body apparatus according to claim 1 wherein
the second movable body is driven in the second direction by a drive device, and
the third movable body moves in the second direction with the second movable body by being pushed in contact to the second movable body driven by the drive device.

10. The movable body apparatus according to claim 9 wherein
the second movable body is driven in a direction separating from the third movable body by the drive device after the third movable body has been moved to a predetermined position in the second direction.

11. The movable body apparatus according to claim 1, the apparatus further comprising:
a static gas bearing blowing out gas from one of the second and the third movable bodies to the other of the second and the third movable bodies, wherein
the second movable body is driven in the second direction by a drive device, and
the third movable body moves in the second direction with the second movable body by being pushed in a non-contact manner via the gas by the second movable body driven by the drive device.

12. The movable body apparatus according to claim 1 wherein
the second movable body is driven in the second direction by a first drive device, and
the third movable body is driven synchronously with the second movable body by a second drive device which is controlled independently from the first drive device in the second direction.

13. The movable body apparatus according to claim 12 wherein
the first drive device and the second drive device use a common stator.

14. The movable body apparatus according to claim 1 wherein
the object support member supports the object in a non-contact manner.

15. The movable body apparatus according to claim 14 wherein
the object support member supports the object in a non-contact manner by blowing out pressurized gas toward the lower surface of the object.

16. The movable body apparatus according to claim 1, the apparatus further comprising:
an interferometer system which irradiates a measurement beam on a reflection surface that the first movable body has, as well as receives the reflected light, and obtains positional information of the first movable body based on the reflected light, wherein
a position of the first movable body within the two-dimensional plane is controlled based on an output of the interferometer system.

17. The movable body apparatus according to claim 1, the apparatus further comprising:
an adjustment device including a holding device which has a holding surface smaller than an area of the object, and of the object, holds a portion facing the holding surface from below the object using the holding device and adjusts a position in a direction intersecting the two-dimensional plane.

18. The movable body apparatus according to claim 17 wherein
the object holding member holds the object in a non-contact manner.

19. The movable body apparatus according to claim 18 wherein
the adjustment device blows out pressurized gas toward the object from the holding member, and also holds the object in a non-contact manner by applying a load in a direction of gravitational force to the object by suctioning gas between the holding device and the object.

20. The movable body apparatus according to claim 17 wherein
a position of the two-dimensional plane of the adjustment device is fixed.

21. The movable body apparatus according to claim 20 wherein
the adjustment device is mounted on a member which is vibrationally separated from the second movable body.

22. The movable body apparatus according to claim 21 wherein
the first movable body holds the object movable in a direction intersecting the predetermined two-dimensional plane.

23. The movable body apparatus according to claim 20 wherein
the object support member supports the object on one side and the other side of the adjustment device in the first direction.

24. The movable body apparatus according to claim 17 wherein
the adjustment device further has a weight cancellation device that cancels a weight of the holding device.

25. An object processing device, comprising:
the movable body apparatus according to claim 17; and
an execution device which executes a predetermined operation from a side opposite to the holding device to a portion held by the holding device of the object, to perform a predetermined processing on the object.

26. The object processing device according to claim 25 wherein
the execution device is an apparatus which forms a predetermined pattern on the object using an energy beam.

27. An exposure apparatus, the apparatus comprising:
the movable body apparatus according to claim 1; and
a pattern formation apparatus which exposes the object with an energy beam and forms a predetermined pattern on the object.

28. The exposure apparatus according to claim 27 wherein
the object is a substrate used in a flat panel display device.

29. A flat-panel display manufacturing method, comprising:
exposing the substrate using the exposure apparatus according to claim 28; and
developing the substrate that has been exposed.

30. A device manufacturing method, comprising:
exposing the object using the exposure apparatus according to claim 27; and developing the object that has been exposed.

31. An exposure apparatus that exposes an object with an energy beam and forms a pattern on the object, the apparatus comprising:
a first movable body which holds an edge of an object placed along a predetermined two-dimensional plane that is parallel to a horizontal plane, and is movable with predetermined strokes at least in a first direction within the two-dimensional plane;
a second movable body which includes an object support member that supports the object from below within a movable range in the first direction of the first movable body, and is movable in a second direction orthogonal to the first direction within the two-dimensional plane along with the first movable body; and
a third movable body which is vibrationally separated from the object support member at least in the first direction, supports the first movable body from below within a movable range of the first movable body in the first direction, and is movable along with the second movable body in the second direction; and
an exposure system which exposes the object with the energy beam.

32. The exposure apparatus according to claim 31 wherein
the second movable body moves in the second direction on a first base member, and the third movable body moves in the second direction on a second base member which is vibrationally separated from the first base member.

33. The exposure apparatus according to claim 31 wherein
the first movable body is supported in a non-contact manner on the third movable body.

34. The exposure apparatus according to claim 31, the apparatus further comprising:
a fourth movable body which is movable in the first direction on the second movable body, wherein
the first movable body moves in the first direction by being induced by the fourth movable body.

35. The exposure apparatus according to claim 34 wherein
when the fourth movable body is driven in the first direction, the first movable body is driven synchronously with the fourth movable body by a first linear motor including a stator provided in the fourth movable body and a mover provided in the first movable body.

36. The exposure apparatus according to claim 34 wherein
when the fourth movable body is driven in the first direction, the first movable body is finely driven in at least one of the second direction and a direction around an axis orthogonal to the two dimensional plane by a second linear motor including a stator provided in the fourth movable body and a mover provided in the first movable body.

37. The exposure apparatus according to claim 31 wherein
the second movable body is driven in the second direction by a drive device,
the second movable body and the third movable body are connected by an interlinking device, and
the third movable body moves in the second direction with the second movable body by being pulled by the second movable body via the interlinking device.

38. The exposure apparatus according to claim 37 wherein
of directions of six degrees of freedom, rigidity of the interlinking device in directions of five degrees of freedom that excludes the second direction is lower than the rigidity in the second direction.

39. The exposure apparatus according to claim 31 wherein
the second movable body is driven in the second direction by a drive device, and
the third movable body moves in the second direction with the second movable body by being pushed in contact to the second movable body driven by the drive device.

40. The exposure apparatus according to claim 39 wherein
the second movable body is driven in a direction separating from the third movable body by the drive device after the third movable body has been moved to a predetermined position in the second direction.

41. The exposure apparatus according to claim 31, the apparatus further comprising:
a static gas bearing which blows out gas from one of the second and third movable bodies to the other of the second and third movable bodies, wherein
the second movable body is driven in the second direction by a drive device, and
the third movable body moves in the second direction with the second movable body by being pushed in a non-contact manner via the gas by the second movable body driven by the drive device.

42. The exposure apparatus according to claim 31 wherein
the second movable body is driven in the second direction by a first drive device,
the third movable body is driven synchronously with the second movable body by a second drive device which is controlled independently from the first drive device in the second direction.

43. The exposure apparatus according to claim 42 wherein
the first drive device and the second drive device use a common stator.

44. The exposure apparatus according to any claim 31 wherein
the object support member supports the object in a non-contact manner.

45. The exposure apparatus according to claim 44 wherein
the object support member supports the object in a non-contact manner by blowing out pressurized gas toward the lower surface of the object.

46. The exposure apparatus according to claim 31, the apparatus further comprising:
a measuring device which measures positional information of the first movable body, wherein
a position within the two-dimensional plane of the first movable body is controlled, based on measurement information from the measuring device.

47. The exposure apparatus according to claim 31, the apparatus further comprising:
an adjustment device which includes a holding device that has a holding surface smaller than an area of the object, and by holding the object from below using the holding device at a part of the object facing the holding surface, adjusts a position in a direction intersecting the two-dimensional plane.

48. The exposure apparatus according to claim 47 wherein
the holding device holds the object in a non-contact manner.

49. The exposure apparatus according to claim 48 wherein
the adjustment device holds the object in a non-contact manner by balancing static pressure occurring between the holding device and the object by pressurized gas blowing out from to the holding device and negative pressure occurring between the holding device and the object by vacuum suction.

50. The exposure apparatus according to claim 47 wherein
a position within the two-dimensional plane of the adjustment device is fixed.

51. The exposure apparatus according to claim 50 wherein
the adjustment device is mounted on a member which is vibrationally separated from the second movable body.

52. The exposure apparatus according to claim 51 wherein
the first movable body movably holds the object in a direction intersecting the predetermined two-dimensional line.

53. The exposure apparatus according to claim 50 wherein
the object support member supports the object at one side and the other side of the adjustment device in the first direction.

54. The exposure apparatus according to claim 47 wherein
the adjustment device further has a weight cancellation device that cancels weight of the holding device.

55. The exposure apparatus according to claim 31 wherein
the object is a substrate used in a flat panel display.

56. A flat-panel display manufacturing method, comprising:
exposing the substrate using the exposure apparatus according to claim 55; and developing the substrate that has been exposed.

57. A device manufacturing method, comprising:
exposing the object using the exposure apparatus according to claim 31; and
developing the object that has been exposed.
